(19) United States
(12) Patent Application Publication
(10) Pub. No.: US 2025/0212592 A1
(43) Pub. Date: Jun. 26, 2025

(54) PHOTOELECTRIC CONVERSION ELEMENT, PHOTOELECTRIC CONVERSION MODULE, ELECTRONIC DEVICE, AND SOLAR CELL MODULE

(71) Applicants: Satoshi YAMAMOTO, Shizuoka (JP); Yuuji TANAKA, Shizuoka (JP)

(72) Inventors: Satoshi YAMAMOTO, Shizuoka (JP); Yuuji TANAKA, Shizuoka (JP)

(21) Appl. No.: 18/846,292

(22) PCT Filed: Mar. 13, 2023
(86) PCT No.: PCT/IB2023/052371

§ 371 Date: Sep. 12, 2024

(30) Foreign Application Priority Data
Mar. 18, 2022 (JP) 2022-044140

(51) Int. Cl. H10K 30/50; H10K 30/40; H10K 30/85; H10K 39/12; H10K 77/10; H10K 85/50

(52) U.S. Cl. CPC H10K 30/50; H10K 30/40; H10K 30/85; H10K 39/12; H10K 77/111; H10K 85/50

(57) ABSTRACT

A photoelectric conversion element includes a support body having flexibility, a perovskite layer, and a second electrode, and an average thickness T₁ (μm) of the support body and an average thickness T₂ (nm) of the perovskite layer satisfy the relationship T₂/T₁≤6.

### TECHNICAL FIELD

The present disclosure relates to a photoelectric conversion element, a photoelectric conversion module, an electronic device, and a solar cell module.

### BACKGROUND ART

In recent years, solar cells utilizing a photoelectric conversion element are expected to be used in wide-ranging applications from the viewpoint of replacing fossil fuels and countering global warming, and also as self-sustaining power sources that do not require battery replacement or power supply wiring. In addition, solar cells as self-sustaining power sources are attracting a lot of attention as one of the energy harvesting technologies used in the Internet of Things (IoT) devices, artificial satellites, and the like.

In addition to inorganic solar cells using silicon that have been widely used conventionally, solar cells include organic solar cells such as dye-sensitized solar cells, organic thin-film solar cells, and perovskite solar cells. A perovskite solar cell can be manufactured by using a conventional printing method without using an electrolyte solution containing an organic solvent and the like, which is advantageous in terms of improvement in safety and reduction of manufacturing cost.

In recent years, as a photoelectric conversion element using a flexible material as a base material, there has been proposed a solid-junction photoelectric conversion element including a first conductive layer, a perovskite layer, and a second conductive layer in this order. In this photoelectric conversion element, a maximum height roughness (Rz) of a surface where the perovskite layer and at least one layer of layers adjacent to both sides of the perovskite layer contact each other is 1 nm or more (see, for example, PTL 1).

### CITATION LIST

### Patent Literature

### [PTL 1]

WO 2017-200000

### SUMMARY OF INVENTION

### Technical Problem

An object of the present invention is to provide a photoelectric conversion element that maintains a high output even after a bending test.

### Solution to Problem

A photoelectric conversion element of the present embodiment as a means for solving the above-described problems includes a support body having flexibility, a perovskite layer, and a second electrode, and an average thickness T₁ (μm) of the support body and an average thickness T₂ (nm) of the perovskite layer satisfy the relationship T₂/T₁≤6.

### Advantageous Effects of Invention

According to the present embodiment, it is possible to provide a photoelectric conversion element that maintains a high output even after a bending test.

### BRIEF DESCRIPTION OF DRAWINGS

A more complete appreciation of embodiments of the present disclosure and many of the attendant advantages and features thereof can be readily obtained and understood from the following detailed description with reference to the accompanying drawings.

FIG. 1 is a schematic diagram illustrating a photoelectric conversion element according to an embodiment of the present invention.

FIG. 2 is a cross-sectional view of a solar cell module according to an embodiment of the present invention.

FIG. 3 is a cross-sectional view of a solar cell module according to an embodiment of the present invention.

FIG. 4 is a cross-sectional view of a solar cell module according to an embodiment of the present invention.

FIG. 5 is a cross-sectional view of a solar cell module according to an embodiment of the present invention.

FIG. 6 is a cross-sectional view of a solar cell module according to an embodiment of the present invention.

FIG. 7 is a schematic diagram illustrating a mouse as an electronic device according to an embodiment of the present invention, including a photoelectric conversion module according to an embodiment of the present invention.

FIG. 8 is a schematic diagram illustrating a mouse in which a photoelectric conversion element is mounted.

FIG. 9 is a schematic diagram illustrating a keyboard used in a personal computer as an electronic device according to an embodiment of the present invention, including a photoelectric conversion module according to an embodiment of the present invention.

FIG. 10 is a schematic diagram illustrating a keyboard in which a photoelectric conversion element is mounted.

FIG. 11 is a schematic diagram illustrating a keyboard in which a small photoelectric conversion element is mounted in a part of keys of the keyboard.

FIG. 12 is a schematic diagram illustrating a sensor as an electronic device according to an embodiment of the present invention, including a photoelectric conversion module according to an embodiment of the present invention.

FIG. 13 is a schematic diagram illustrating a turntable as an electronic device according to an embodiment of the present invention, including a photoelectric conversion module according to an embodiment of the present invention.

FIG. 14 is a schematic diagram illustrating an electronic device in which a photoelectric conversion element and/or a photoelectric conversion module according to embodiments of the present invention are/is combined with a device that operates on electric power generated by photoelectric conversion by the photoelectric conversion element and/or the photoelectric conversion module.

FIG. 15 is a schematic diagram illustrating a case in which a power supply IC for the photoelectric conversion element is incorporated between the photoelectric conversion element and a circuit of the device in FIG. 14.

FIG. 16 is a schematic diagram illustrating a case in which a power storage device is incorporated between the power supply IC and the circuit of the device in FIG. 15.

FIG. 17 is a schematic diagram illustrating a power supply module including a photoelectric conversion element and/or a photoelectric conversion module according to embodiments of the present invention, and a power supply IC.

FIG. 18 is a schematic diagram illustrating a power supply module in which a power storage device is added to the power supply IC in FIG. 17.

FIG. 19 is a graph in which a relationship between a maintenance rate of photoelectric conversion efficiency after a second durability test and values of T₂/T₁ in Examples 1 to 31 and Comparative Examples 1 to 13 are plotted.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below.

As used herein, the singular forms “a,” “an,” and “the” are intended to include the plural forms as well, unless the context clearly indicates otherwise.

As a result of extensive studies, the inventors of the present invention have found the following.

In the case of a conventional photoelectric conversion element, a highly flexible support body is used, and thus, there is a problem in that cracks are likely to occur in a perovskite layer, making it difficult to satisfy desired output characteristics.

With regard to the problems described above, the present inventors found that, by adjusting the thickness of the flexible support body and the thickness of the perovskite layer, that is, when “the thickness of the perovskite layer/the thickness of the support body≤6 is satisfied”, and by forming a perovskite layer having a specific composition, cracks are less likely to occur even in an element having flexibility, and it is possible to obtain a photoelectric conversion element having high output.

### (Photoelectric Conversion Element)

The photoelectric conversion element according to the present embodiment includes a support body having flexibility, a perovskite layer, and a second electrode, and if desired, includes a first electrode, a hole blocking layer, an electron transport layer, a hole transport layer, an electrode protection layer, and other layers.

In the specification of the present application, the term “photoelectric conversion element” refers to an element that converts light energy into electrical energy or an element that converts electrical energy into light energy. Specific examples of the photoelectric conversion element include, but are not limited to, a solar cell and a photodiode.

In the present embodiment, the layers mentioned above may each be a single film (single layer), or may be a laminate in which a plurality of films overlap.

A lamination direction refers to a direction perpendicular to a plane direction of each layer in the photoelectric conversion element. In addition to a physical contact, a connection also refers to an electrical connection to the extent that the effects of the present embodiment can be achieved.

### <Support Body>

The photoelectric conversion element of the present embodiment includes a support body having flexibility.

In the present embodiment, having flexibility means that the support body has a property of being flexibly bent by an external force, and does not break even when being bent at a bending radius (R) of at least 15 mm.

A shape, a structure, and a size of the support body are not particularly limited, and can be appropriately selected according to a purpose.

The material of the support body is not particularly limited, as long as the material has flexibility and can be appropriately selected according to a purpose. Examples of the material of the support body include, but are not limited to, glass, a plastic film, ceramic, and metal. Among these materials, a material having heat resistance to a baking temperature is preferable if a baking process is included in the formation of the electron transport layer described later. If the support body is formed of a material having conductivity such as metal, the support body can also serve as the first electrode.

An average thickness T₁ (μm) of the support body is not particularly limited, as long as flexibility is exhibited at the thickness, and can be appropriately selected according to a purpose. The average thickness T₁ (μm) of the support body is preferably 30 μm or more and 1300 μm or less, and more preferably 50 μm or more and 125 μm or less. If the average thickness T₁ (μm) of the support body is 30 μm or more and 1300 μm or less, the flexibility of the support body can be improved.

In the photoelectric conversion element of the present embodiment, the average thickness T₁ (μm) of the support body and an average thickness T₂ (nm) of the perovskite layer described later satisfy the following relationship T₂/T₁≤6.

The inventors of the present invention have found that, when the average thickness T₁ (μm) of the support body and the average thickness T₂ (nm) of the perovskite layer described above satisfy the following relationship T₂/T₁≤6, even if a support body having flexibility is used as a base material, it is possible to prevent cracks from occurring in the perovskite layer due to strain, warping, or twisting when the photoelectric conversion element is bent, and a high output can be maintained even after a bending test is conducted over a long period of time.

The ratio (T₂/T₁) of the average thickness T₁ (μm) of the support body and the average thickness T₂ (nm) of the perovskite layer is 6 or less, preferably 2 or more and 6 or less, and more preferably 4 or more and 6 or less.

If the support body and the first electrode are provided separately, the support body may be provided in either one or both of an outermost portion on a side of the first electrode or an outermost portion on a side of the second electrode of the photoelectric conversion element. Hereinafter, the support body (substrate) provided in the outermost portion on the side of the first electrode may be referred to as a first substrate, and the substrate provided in the outermost portion on the side of the second electrode may be referred to as a second substrate.

### <First Electrode>

The first electrode may also serve as a support body having flexibility and conductivity, and may be provided separately from the support body having flexibility.

If the support body and the first electrode are provided separately, a shape and a size of the first electrode are not particularly limited, and can be appropriately selected according to a purpose.

The first electrode is preferably separated from the second electrode, which will be described later, by the hole transport layer.

The structure of the first electrode is not particularly limited and can be appropriately selected according to a purpose. The first electrode may have a single-layer structure or a structure in which a plurality of materials are laminated.

The material of the first electrode is not particularly limited, as long as the material has conductivity and can be appropriately selected according to a purpose. Examples of the material of the first electrode include, but are not limited to, transparent conductive metal oxides, carbon, and metals.

Examples of the transparent conductive metal oxides include, but are not limited to, indium tin oxide (hereinafter, referred to as “ITO”), fluorine-doped tin oxide (hereinafter, referred to as “FTO”), antimony-doped tin oxide (hereinafter, referred to as “ATO”), niobium-doped tin oxide (hereinafter, referred to as “NTO”), aluminum-doped zinc oxide (hereinafter, referred to as “AZO”), indium and zinc oxides, and niobium and titanium oxides.

Examples of the carbon include, but are not limited to, carbon black, carbon nanotubes, graphene, and fullerene.

Examples of the metals include, but are not limited to, gold, silver, aluminum, nickel, indium, tantalum, and titanium.

Each of these may be used alone or in combination with others. Among these materials, transparent conductive metal oxides with a high transparency are preferred, and ITO, FTO, ATO, NTO, and AZO are more preferred.

The average thickness of the first electrode is not particularly limited and can be appropriately selected according to a purpose, but is preferably 5 nm or more and 100 μm or less, and more preferably 50 nm or more and 10 μm or less. If the material of the first electrode is carbon or a metal, it is preferable that the average thickness of the first electrode is selected so that transparency is obtained.

A method of forming the first electrode is not particularly limited and can be appropriately selected according to a purpose. Examples of the method include, but are not limited to, the well-known methods of sputtering, vapor deposition, and spraying.

The first electrode is preferably formed on the support body (the first substrate), and it is possible to use an integrated commercial product in which the first electrode is formed on the support body (the first substrate) in advance.

Examples of the integrated commercial product include, but are not limited to, an FTO-coated transparent plastic film and an ITO-coated transparent plastic film.

Other examples of the integrated commercial product include a glass substrate provided with a transparent electrode obtained by doping tin oxide or indium oxide with cations or anions having different valences, or a metal electrode having a mesh-like or stripe-like structure that allows the passing of light.

Each of these may be used alone or in combination with others by mixing or laminating. In addition, a metal lead wire or the like may be jointly used for the purpose of lowering an electrical resistance value.

Examples of a material of the metal lead wire include, but are not limited to, aluminum, copper, silver, gold, platinum, and nickel.

The metal lead wire can be jointly used by forming the metal lead wire on the substrate by vapor deposition, sputtering, pressure bonding, or the like, and providing a layer of ITO or FTO above the formed metal lead wire.

### <Electron Transport Layer>

The electron transport layer is a layer that transports electrons generated in the perovskite layer, which will be described later, to the first electrode. For this reason, the electron transport layer is preferably arranged adjacent to the first electrode.

A shape and a size of the electron transport layer are not particularly limited, as long as electron transport layers in at least two photoelectric conversion elements adjacent to each other are separated by the hole transport layer described later, and can be appropriately selected according to a purpose.

By separating the electron transport layers in at least two photoelectric conversion elements adjacent to each other by the hole transport layer, electron diffusion is suppressed, which reduces a leakage current, and thus, light durability can be improved.

The structure of the electron transport layer may be a single layered structure or a multi-layered structure in which a plurality of layers are laminated. The multi-layered structure is preferable, and a structure formed by a layer having a dense structure (dense layer) and a layer having a porous structure (porous layer) is more preferable.

The dense layer is preferably arranged on a side closer to the first electrode than the porous layer.

### <<Dense Layer>>

The dense layer is not particularly limited, as long as the dense layer contains an electron-transporting material and is denser than the porous layer described later. The dense layer can be appropriately selected according to a purpose, and a semiconductor material is preferably used.

The semiconductor material is not particularly limited, and well-known materials can be used. Examples of the semiconductor material include, but are not limited to, elemental semiconductors and compounds including compound semiconductors.

Examples of the elemental semiconductors include, but are not limited to, silicon and germanium.

Examples of the compound semiconductors include, but are not limited to, metal chalcogenides, specifically, oxides of titanium, tin, zinc, iron, tungsten, zirconium, hafnium, strontium, indium, cerium, yttrium, lanthanum, vanadium, niobium, and tantalum; sulfides of cadmium, zinc, lead, silver, antimony, and bismuth; selenides of cadmium and lead; and tellurides of cadmium. Other compound semiconductors include, but are not limited to, phosphides of zinc, gallium, indium, and cadmium; gallium arsenide; copper-indium-selenide; and copper-indium-sulfide.

Among the compound semiconductors, oxide semiconductors are preferred, and particularly, compound semiconductors containing titanium oxide, zinc oxide, tin oxide, and niobium oxide are more preferred. In particular, if a compound semiconductor contains at least one of tin oxide and titanium oxide, the output is improved. This improvement is considered to be a result of the fact that re-bonding is less likely to occur at the interface between the dense layer and the perovskite layer.

Each of the semiconductor materials may be used alone or in combination with others. A crystal form of the semiconductor material is not particularly limited, can be appropriately selected according to a purpose, and may be a single crystal, a polycrystal, or an amorphous form.

The dense layer preferably contains at least one of a phosphonic acid compound, a boronic acid compound, a sulfonic acid compound, a silyl halide compound, and an alkoxysilyl compound on the electron-transporting material at the surface on a side of the perovskite layer. If these compounds are contained on the electron-transporting material at the surface of the dense layer on the side of the perovskite layer, it can be expected that the physical properties of the interface between the dense layer and the perovskite layer are controlled. In other words, by coating the electron-transporting material at the surface of the dense layer on the side of the perovskite layer with these compounds, the effects of reducing the interface resistance between the dense layer and the perovskite layer and smoothing the electron transfer can be expected.

These compounds may be bonded to the electron-transporting material. Examples of the bonding include, but are not limited to, covalent bonding and ionic bonding.

The compound is at least one of a phosphonic acid compound, a boronic acid compound, a sulfonic acid compound, a silyl halide compound, and an alkoxysilyl compound.

From the viewpoint of compatibility with the perovskite layer described later, the compound preferably includes a nitrogen atom.

The phosphonic acid compound is not particularly limited, as long as the compound contains a phosphonic acid group, and can be appropriately selected according to a purpose. A specific example will be described later.

The boronic acid compound is not particularly limited, as long as the compound contains a boronic acid group, and can be appropriately selected according to a purpose. A specific example will be described later.

The sulfonic acid compound is not particularly limited, as long as the compound contains a sulfonic acid group, and can be appropriately selected according to a purpose. A specific example will be described later.

The silyl halide compound is not particularly limited, as long as the compound contains a silyl halide group, and can be appropriately selected according to a purpose. A specific example will be described later.

The alkoxysilyl compound is not particularly limited, as long as the compound contains an alkoxysilyl group, and can be appropriately selected according to a purpose. A specific example will be described later.

The molecular weight of the compound is not particularly limited, and can be appropriately selected according to a purpose. Examples of the molecular weight include, but are not limited to, a molecular weight of 100 or more and 500 or less.

The compound is represented, for example, by General Formula (X) below.

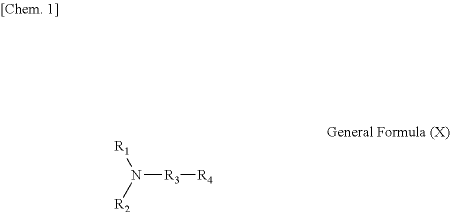

In General Formula (X) mentioned above, R₁ and R₂ represent a hydrogen atom, an alkyl group, an aryl group, or a heterocycle, and may be the same or different. R₃ represents a divalent alkylene group, a divalent aryl group, or a divalent heterocycle, and R₄ represents a phosphonic acid group, a boronic acid group, a sulfonic acid group, a silyl halide group, or an alkoxysilyl group. R₁ or R₂, and R₃, and N may together form a ring structure.

Examples of the compound include, but are not limited to, the following compounds.

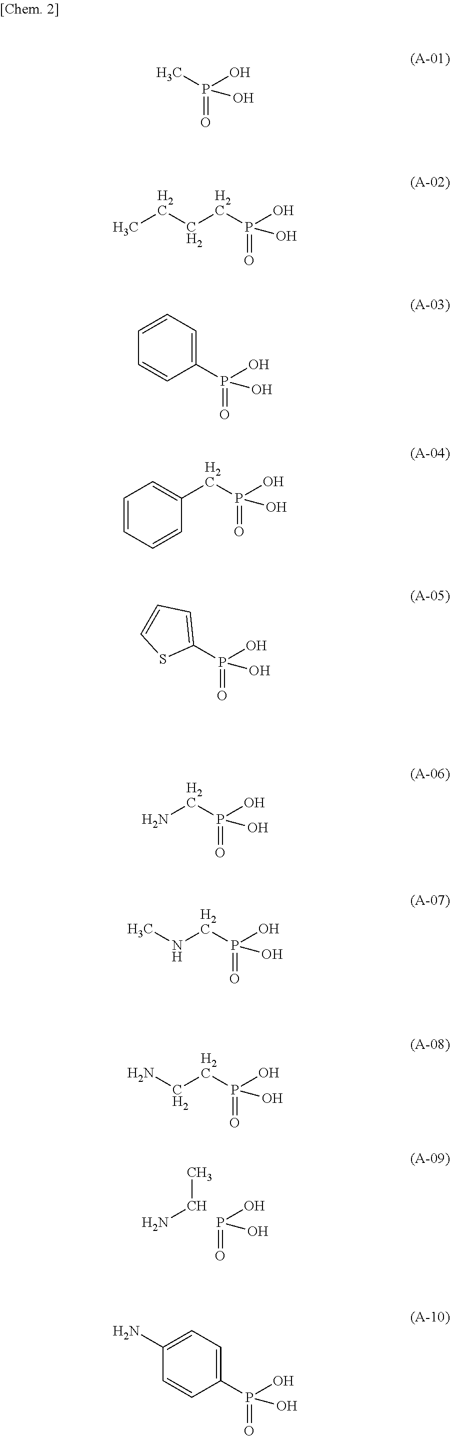

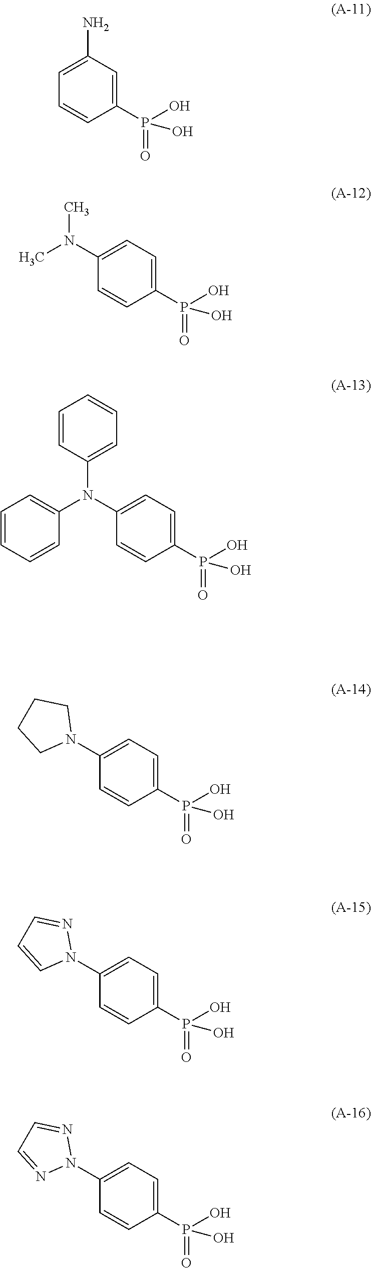 [SMILES: Nc1cccc(P(=O)(O)O)c1 ; CN(C)c1ccc(P(=O)(O)O)cc1 ; O=P(O)(O)c1ccc(N(c2ccccc2)c2ccccc2)cc1 ; O=P(O)(O)c1ccc(N2CCCC2)cc1 ; O=P(O)(O)c1ccc(-n2cccn2)cc1 ; O=P(O)(O)c1ccc(-n2nccn2)cc1]

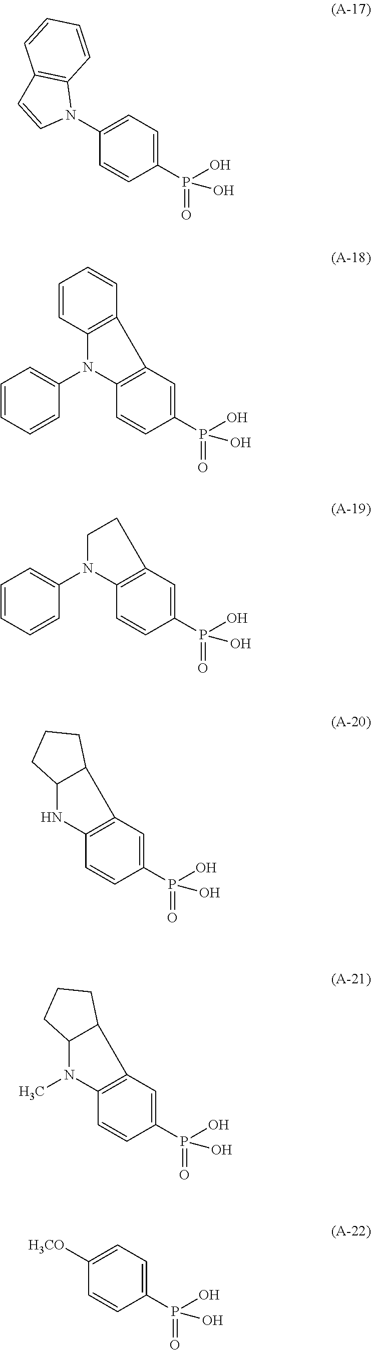 [SMILES: O=P(O)(O)c1ccc(-n2ccc3ccccc32)cc1 ; O=P(O)(O)c1ccc2c(c1)c1ccccc1n2-c1ccccc1 ; O=P(O)(O)c1ccc2c(c1)CCN2c1ccccc1 ; O=P(O)(O)c1ccc2c(c1)C1CCCC1N2 ; CN1c2ccc(P(=O)(O)O)cc2C2CCCC21 ; COc1ccc(P(=O)(O)O)cc1]

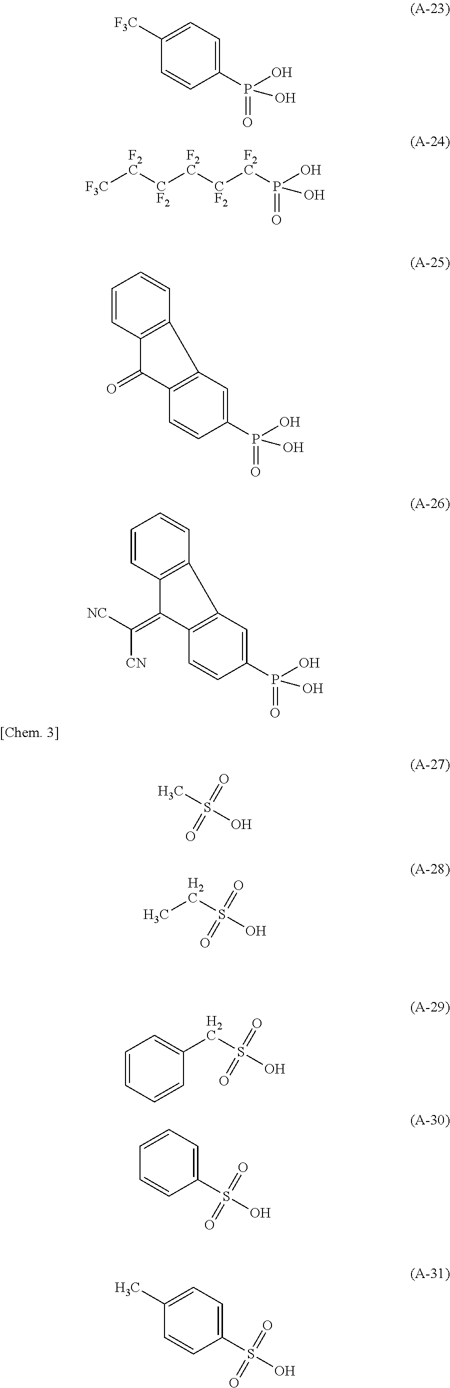

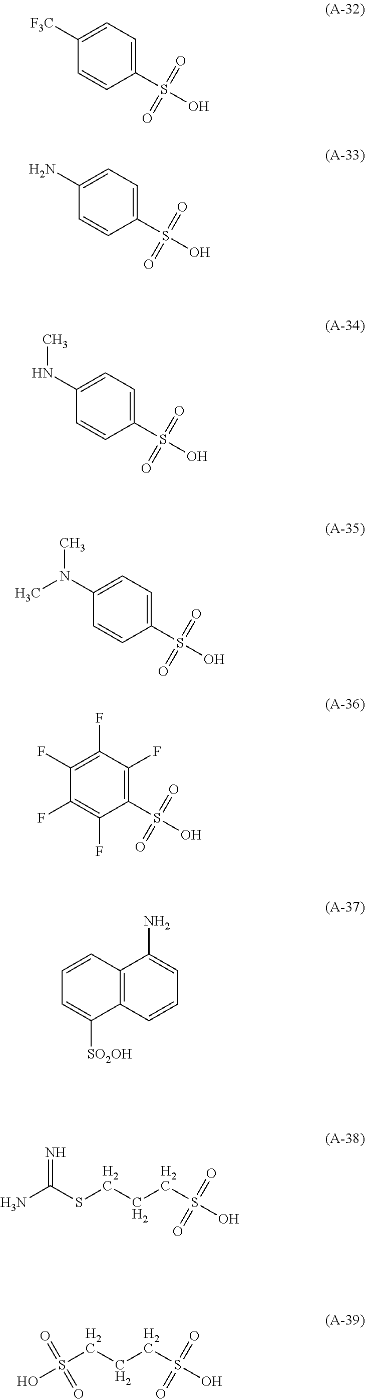

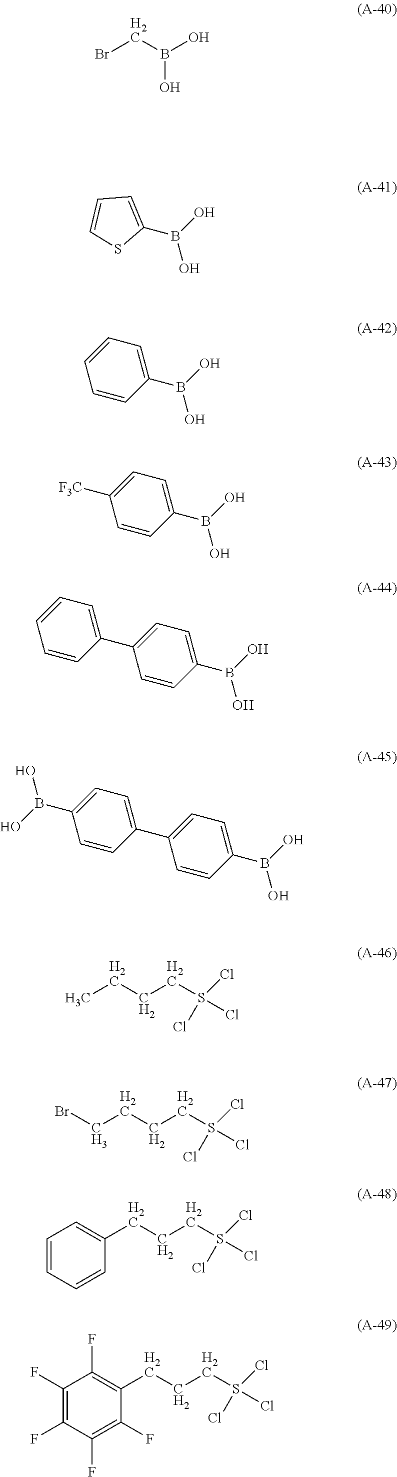

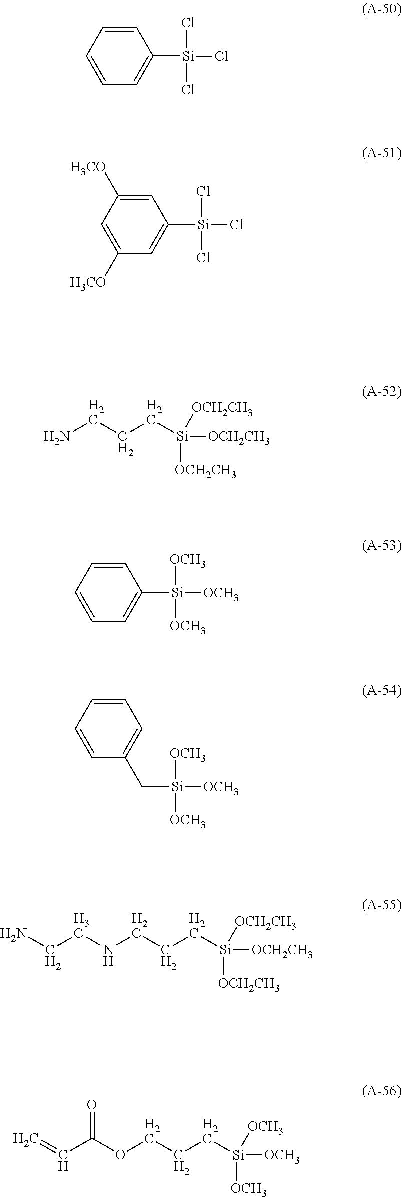

It is preferable to coat the surface of the metal oxide on the dense layer with a compound including a substituent that reacts with the metal oxide, such as phosphonic acid, sulfonic acid, or a silyl halide group.

Specific examples of the compound for coating the surface include, but are not limited to, methylphosphonic acid, phenylphosphonic acid, phenethylphosphonic acid, (1-aminoethyl)phosphonic acid, (2-aminoethyl)phosphonic acid, methanesulfonic acid, benzenesulfonic acid, 2-thienylboronic acid, methyltrichlorosilane, and n-hexyltriethoxy silane.

The average thickness of the dense layer is not particularly limited and can be appropriately selected according to a purpose, but is preferably 5 nm or more and 1 μm or less, and more preferably 10 nm or more and 700 nm or less.

The surface of the dense layer on the side of the perovskite layer is preferably as smooth as possible.

As one indicator of smoothness, it is preferable that the roughness factor is small. However, considering the relationship with the average thickness of the dense layer, the roughness factor of the dense layer on the side of the perovskite layer is preferably 20 or less, and more preferably 10 or less. A value of the lower limit of the roughness factor is not particularly limited, can be appropriately selected according to a purpose, and examples thereof include, but are not limited to, 1 or more.

The roughness factor is the ratio of the actual surface area to the apparent surface area, and is also called Wenzel roughness factor. The actual surface area can be measured, for example, by measuring the BET specific surface area, and the roughness factor can be obtained by dividing the measured value by the apparent surface area.

A method of manufacturing the dense layer is not particularly limited and can be appropriately selected according to a purpose. Examples of the method include, but are not limited to, a method of forming a thin film in a vacuum (vacuum film-forming method) and a wet film-forming method.

Examples of the vacuum film-forming method include, but are not limited to, a sputtering method, a pulse laser deposition method (PLD method), an ion beam sputtering method, an ion assisted method, an ion plating method, a vacuum vapor deposition method, an atomic layer deposition method (ALD method), and a chemical vapor deposition method (CVD method).

Examples of the wet film-forming method include, but are not limited to, a sol-gel method. The sol-gel method is a method in which a gel is manufactured from a solution by a chemical reaction such as hydrolysis and polymerization/condensation, and then, the gel is treated by heat to promote densification. If the sol-gel method is used, a method of applying the sol solution is not particularly limited and can be appropriately selected according to a purpose. Examples of the method of applying the sol solution include, but are not limited to, a dip method, a spray method, a wire bar method, a spin coating method, a roller coating method, a blade coating method, a gravure coating method, and a wet printing method including, but not being limited to, letterpress, offset, gravure, intaglio, rubber plate, and screen printing. The temperature in the heat treatment after applying the sol solution is preferably 80° C. or higher, and more preferably 100° C. or higher.

### <<Porous Layer>>

The porous layer is not particularly limited, as long as the porous layer is a layer that contains an electron-transporting material and is less dense than the dense layer (is porous), and can be appropriately selected according to a purpose. Note that “less dense than the dense layer” means that a packing density of the porous layer is lower than a packing density of the dense layer.

The electron-transporting material is not particularly limited and can be appropriately selected according to a purpose, but similar to the dense layer, a semiconductor material is preferable. The semiconductor material in the porous layer may be similar to the semiconductor material in the dense layer.

It is preferable that the electron-transporting material forming the porous layer has a particle-like shape, and a porous film is formed by bonding the particles.

The number average particle diameter of primary particles of the electron-transporting material is not particularly limited and can be appropriately selected according to a purpose, but is preferably 1 nm or more and 100 nm or less, and more preferably 10 nm or more and 50 nm or less. A semiconductor material having a particle diameter larger than the number average particle diameter may be mixed to or laminated on the electron-transporting material, to improve the conversion efficiency by the effect of scattering incident light.

In this case, the number average particle diameter is preferably 50 nm or more and 500 nm or less.

Titanium oxide particles can be suitably used as the electron-transporting material in the porous layer.

If the electron-transporting material in the porous layer is formed of titanium oxide particles, the conduction band is high, and a high open-circuit voltage can be obtained.

If the electron-transporting material in the porous layer is formed of titanium oxide particles, the refractive index is high, and a high short-circuit current can be obtained by the light confinement effect.

Further, if the electron-transporting material in the porous layer is formed of titanium oxide particles, it is advantageous from the viewpoint that the dielectric constant of the porous layer increases and the mobility of electrons increases, so that a high fill factor (form factor) can be obtained.

That is, it is possible to improve the open-circuit voltage and the fill factor, and therefore, it is preferable that the electron transport layer includes a porous layer containing titanium oxide particles.

The average thickness of the porous layer is not particularly limited and can be appropriately selected according to a purpose, but is preferably 30 nm or more and 1 μm or less, and more preferably 100 nm or more and 600 nm or less.

The porous layer may have a multi-layer structure. A porous layer having a multi-layered structure may be manufactured by applying a liquid dispersion of particles of an electron-transporting material having different particle diameters a plurality of times, or applying a liquid dispersion including materials having different compositions such as an electron transport material, a resin, and an additive a plurality of times. If the liquid dispersion of particles of the electron-transporting material is applied a plurality of times, there is also an effect of adjusting the average thickness (film thickness) of the porous layer.

### <Perovskite Layer>

The perovskite layer is a layer that contains a perovskite compound and absorbs light to sensitize the electron transport layer. Therefore, the perovskite layer is preferably arranged adjacent to the electron transport layer.

In the photoelectric conversion element of the present embodiment, the perovskite layer preferably contains at least one of an alkali metal and a transition metal, and further contains other components, as desired.

By including at least one of the alkali metal and the transition metal in the perovskite layer, a longer carrier life, a lower interface defect density, and a faster charge movement speed are obtained, and as a result, it is possible to achieve better photoelectric conversion characteristics and durability. Considering a valence state of the perovskite material in the lattice, any alkali metal cation including a monovalent cation is considered to exhibit the functions described above.

The alkali metal is not particularly limited, as long as the alkali metal is an element belonging to Group 1 elements in the periodic table defined by the International Union of Pure and Applied Chemistry (IUPAC), and can be appropriately selected according to a purpose. Examples of the alkali metal include, but are not limited to, lithium, sodium, potassium, rubidium, cesium, and francium. Among the alkali metals, cesium and rubidium are preferred.

The transition metal is not particularly limited, as long as the transition metal is an element belonging to Groups 3 to 11 in the periodic table defined by IUPAC, and can be appropriately selected according to a purpose. Examples of the transition element include, but are not limited to, copper, silver, and gold.

The total content of the alkali metal and the transition metal is preferably 0.1 mass % or more and 50 mass % or less, more preferably 1 mass % or more and 30 mass % or less, relative to the total mass of the perovskite layer.

The shape and the size of the perovskite layer are not particularly limited, and can be appropriately selected according to a purpose.

### <<Perovskite Compound>>

A perovskite compound is a composite material of an organic compound and an inorganic compound, and is represented by General Formula (3) below.

X_{α}Y_{β}M_{γ} General Formula (3)

In General Formula (3) described above, the ratio of α:β:γ is 3:1:1, and β and γ represent integers greater than 1. Note that even if the ratio does not strictly match the above-mentioned ratio due to crystal defects or the like, it is sufficient to obtain a ratio at which the perovskite layer can function.

In General Formula (3) described above, X represents a halogen ion.

The halogen ion is not particularly limited, as long as the halogen ion is an element belonging to Group 17 in the periodic table defined by the International Union of Pure and Applied Chemistry (IUPAC), and can be appropriately selected according to a purpose. Examples of the halogen ion include, but are not limited to, chlorine, bromine, and iodine. Each of these may be used alone or in combination with others.

In General Formula (3) described above, Y represents a monovalent cation including an amino group.

Examples of the monovalent cation including an amino group include, but are not limited to, a monovalent organic cation and a monovalent inorganic cation. In particular, it is preferable to include two or more types of monovalent cations selected from monovalent organic cations and monovalent inorganic cations. If the monovalent cation including an amino group contains two or more types of monovalent cations selected from the monovalent organic cation and the monovalent inorganic cation, it is possible to make the crystal structure of the perovskite layer more complex, so that the perovskite layer does not easily crack and the durability can be improved.

An example of the monovalent organic cation includes, but is not limited to, an alkylamine compound ion.

The alkylamine compound ion is not particularly limited and can be appropriately selected according to a purpose. Examples of the alkylamine compound ion include, but are not limited to, methylammonium (CH₃NH₃⁺; MA), ethylammonium, n-butylammonium, and formamidinium (CH₃(NH₃)₂⁺; FA).

Examples of the monovalent inorganic cation include, but are not limited to, a cesium ion, a potassium ion, and a rubidium ion.

In the case of a lead halide-methylammonium perovskite compound, if the halogen ion is a chloride ion (Cl⁻), a peak λmax of the light absorption spectrum shifts by about 350 nm, if the halogen ion is a bromide ion (Br⁻), the peak λmax shifts by about 410 nm, and if the halogen ion is an iodide ion (I⁻), the peak λmax shifts by about 540 nm in this order to a long wavelength side, so that a usable spectrum width (band range) is different.

In General Formula (3) described above, M represents one or more metal ions including lead (Pb).

The metal of the metal ion is not particularly limited and can be appropriately selected according to a purpose. Examples of the metal include, but are not limited to, lead, indium, antimony, tin, copper, and bismuth.

The perovskite layer preferably has a layered perovskite structure in which a layer formed by a metal halide and a layer in which organic cation molecules are arranged are alternately laminated.

A method of forming the perovskite layer is not particularly limited and can be appropriately selected according to a purpose. Examples of the method include, but are not limited to, a method of applying a solution in which a metal halide and an alkylamine halide or cesium halide are dissolved or dispersed, and then drying the applied solution.

The method of forming the perovskite layer also includes, but is not limited to, a two-step precipitation method in which a solution of a dissolved or dispersed metal halide is applied and dried, and then immersed in a solution of a dissolved alkylamine halide to form a perovskite compound.

The method of forming the perovskite layer further includes, but is not limited to, a method of adding a poor solvent (a solvent with low solubility) with respect to the perovskite compound while applying a solution of a dissolved or dispersed metal halide and alkylamine halide to precipitate a crystal.

In addition, the method of forming the perovskite layer includes, but is not limited to, a method of vapor-depositing a metal halide in a gas filled with methylamine (methylammonium; MA) and the like.

Among these methods, the method of adding a poor solvent with respect to the perovskite compound while applying a solution of a dissolved or dispersed metal halide and alkylamine halide to precipitate a crystal is preferred.

The method of applying the solution is not particularly limited and can be appropriately selected according to a purpose. Examples of the method include, but are not limited to, an immersion method, a spin coating method, a spray method, a dip method, a roller method, and an air knife method. The method of applying the solution may also be a method of precipitating in a supercritical fluid using carbon dioxide or the like.

The perovskite layer may contain a sensitizing dye.

A method of forming the perovskite layer containing the sensitizing dye is not particularly limited and can be appropriately selected according to a purpose. Examples of the method include, but are not limited to, a method of mixing a perovskite compound and a sensitizing dye, and a method of adsorbing the sensitizing dye after forming the perovskite layer.

The sensitizing dye is not particularly limited, as long as the sensitizing dye is a compound that is photoexcited by the excitation light being used, and can be appropriately selected according to a purpose.

Examples of the sensitizing dye include, but are not limited to, metal complex compounds, coumarin compounds, polyene compounds, indoline compounds, thiophene compounds, cyanine dyes, merocyanine dyes, 9-arylxanthene compounds, triarylmethane compounds, phthalocyanine compounds, and porphyrin compounds.

Examples of the metal complex compound include, but are not limited to, compounds described in Japanese Translation of PCT International Application Publication No. H7-500630, Japanese Unexamined Patent Application Publication No. H10-233238, Japanese Unexamined Patent Application Publication No. 2000-26487, Japanese Unexamined Patent Application Publication No. 2000-323191, and Japanese Unexamined Patent Application Publication No. 2001-59062.

Examples of the coumarin compound include, but are not limited to, compounds described in Japanese Unexamined Patent Application Publication No. H10-93118, Japanese Unexamined Patent Application Publication No. 2002-164089, Japanese Unexamined Patent Application Publication No. 2004-95450, and J. Phys. Chem. C, 7224, Vol. 111 (2007).

Examples of the polyene compound include, but are not limited to, compounds described in Japanese Unexamined Patent Application Publication No. 2004-95450 and Chem. Commun., 4887 (2007).

Examples of the indoline compound include, but are not limited to, compounds described in Japanese Unexamined Patent Application Publication No. 2003-264010, Japanese Unexamined Patent Application Publication No. 2004-63274, Japanese Unexamined Patent Application Publication No. 2004-115636, Japanese Unexamined Patent Application Publication No. 2004-200068, Japanese Unexamined Patent Application Publication No. 2004-235052, J. Am. Chem. Soc., 12218, Vol. 126 (2004), Chem. Commun., 3036 (2003), and Angew. Chem. Int. Ed., 1923, Vol. 47 (2008).

Examples of the thiophene compound include, but are not limited to, compounds described in J. Am. Chem. Soc., 16701, Vol. 128 (2006) and J. Am. Chem. Soc., 14256, Vol. 128 (2006). Examples of the cyanine dye include, but are not limited to, compounds described in Japanese Unexamined Patent Application Publication No. H11-86916, Japanese Unexamined Patent Application Publication No. H11-214730, Japanese Unexamined Patent Application Publication No. 2000-106224, Japanese Unexamined Patent Application Publication No. 2001-76773, and Japanese Unexamined Patent Application Publication No. 2003-7359. Examples of the merocyanine dyes include, but are not limited to, compounds described in Japanese Unexamined Patent Application Publication No. H11-214731, Japanese Unexamined Patent Application Publication No. H11-238905, Japanese Unexamined Patent Application Publication No. 2001-52766, Japanese Unexamined Patent Application Publication No. 2001-76775, and Japanese Unexamined Patent Application Publication No. 2003-7360.

Examples of the 9-arylxanthene compounds include, but are not limited to, compounds described in Japanese Unexamined Patent Application Publication No. H10-92477, Japanese Unexamined Patent Application Publication No. H11-273754, Japanese Unexamined Patent Application Publication No. H11-273755, and Japanese Unexamined Patent Application Publication No. 2003-31273.

Examples of the triarylmethane compounds include, but are not limited to, compounds described in Japanese Unexamined Patent Application Publication No. H10-93118 and Japanese Unexamined Patent Application Publication No. 2003-31273.

Examples of the phthalocyanine compound include, but are not limited to, compounds described in Japanese Unexamined Patent Application Publication No. H9-199744, Japanese Unexamined Patent Application Publication No. H10-233238, Japanese Unexamined Patent Application Publication No. H11-204821, Japanese Unexamined Patent Application Publication No. H11-265738, J. Phys. Chem., 2342, Vol. 91 (1987), J. Phys. Chem. B, 6272, Vol. 97 (1993), Electroanal. Chem., 31, Vol. 537 (2002), Japanese Unexamined Patent Application Publication No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008).

Among these compounds, metal complex compounds, indoline compounds, thiophene compounds, and porphyrin compounds are preferred.

The average thickness T₂ (nm) of the perovskite layer is preferably 50 nm or more and 800 nm or less, more preferably 50 nm or more and 500 nm or less, and even more preferably 50 nm or more and 400 nm or less. If the average thickness T₂ (nm) is 50 nm or more, the perovskite layer absorbs less light, and thus, there is insufficient carrier generation. If the average thickness is 500 nm or less, the transport efficiency of the carriers generated by light absorption does not decrease further.

The average thickness T₂ (nm) of the perovskite layer can be measured, for example, by cross-sectional SEM measurement.

### <Film Containing Compound Represented by General Formula (2)>

The photoelectric conversion element of the present embodiment may include a film containing the compound represented by General Formula (2) below between the perovskite layer, as a photoelectric conversion layer, and the hole transport layer.

A-X General Formula (2)

In General Formula (2) described above, A represents a monovalent cation, and X represents a monovalent anion.

The photoelectric conversion element of the present embodiment includes a film containing the compound represented by General Formula (2) described above between the perovskite layer and the hole transport layer, and thus, it can be expected that the physical properties at the interface are controlled.

The compound (an organic salt or an inorganic salt) represented by General Formula (2) described above is preferably a salt different from the salt forming the perovskite layer.

The salt is not particularly limited and can be appropriately selected according to a purpose, but is preferably a salt including a halogen atom from the viewpoint of compatibility with the perovskite compound. Examples of the halogen atom include, but are not limited to, chlorine, iodine, and bromine.

The organic salt is preferably a hydrohalogenic acid salt of an amine from the viewpoint of compatibility with the perovskite compound.

The inorganic salt is preferably a halide of an alkali metal from the viewpoint of compatibility with the perovskite compound. Examples of the alkali metal include, but are not limited to, lithium, sodium, potassium, rubidium, and cesium.

Examples of A include, but are not limited to, quaternary amino cation compounds, pyridinium cation compounds, imidazolinium cation compounds, pyrrolidinium cation compounds, and phosphonium cation compounds.

Examples of the quaternary amino cation compounds include, but are not limited to, monoalkylammonium cations, dialkylammonium cations, trialkylammonium cations, tetraalkylammonium cations, trialkylarylammonium cations, dialkyldiarylammonium cations, triarylmethylammonium cations, and phenethylammonium cations.

Examples of the pyridinium cation compounds include, but are not limited to, triarylbenzylpyridinium cations, N-alkylpyridinium cations, and N-benzylpyridinium cations.

Examples of the imidazolinium cation compounds include, but are not limited to, N-methyl-2-imidazolinium cations and N-n-propyl-2-methylimidazolinium cations.

Examples of the pyrrolidinium cation compounds include, but are not limited to, 1-ethyl-1-methylpyrrolidinium cations and 1-n-hexyl-1-methylpyrrolidinium cations.

Examples of the phosphonium cation compounds include, but are not limited to, tri-isobutylmethylphosphonium cations and tetra-n-hexyldodecylphosphonium cations.

These organic cations may include a substituent. Each of these organic cations may be used alone or in combination with others.

Examples of X include, but are not limited to, halogen anions such as fluorine anions, chlorine anions, bromine anions, and iodine anions.

Among these anions, it is preferable that A is a cationic compound containing nitrogen and X is a halogen ion.

More specifically, A is more preferably a monoalkylammonium cation, a dialkylammonium cation, a trialkylammonium cation, a tetraalkylammonium cation, or a phenethylammonium cation, and X is more preferably a bromine anion or an iodine anion.

A method of forming a film containing the compound (the organic salt or the inorganic salt) represented by General Formula (2) described above between the photoelectric conversion layer and the hole transport layer is not particularly limited, and can be appropriately selected according to a purpose. Examples of the method include, but are not limited to, a method of applying a solution containing the compound (the organic salt or the inorganic salt) represented by General Formula (2) described above onto the perovskite layer, drying the applied solution, and then, forming a hole transport layer above the dried solution. Examples of the solution include, but are not limited to, an aqueous solution and an alcohol solution. The coating method is not particularly limited and can be appropriately selected according to a purpose. Examples of the coating method include, but are not limited to, an immersion method, an air knife method, a dip method, a spray method, a wire bar method, a spin coating method, a roller coating method, a blade coating method, and a gravure coating method. The method of applying the solution may also be a method of precipitating in a supercritical fluid using carbon dioxide or the like. Moreover, there is no limitation on the film thickness of the layer, and the film may be adsorbed as a single molecule or be in the form of islands without continuity.

The temperature in the drying treatment after applying the solution is not particularly limited, and can be appropriately selected according to a purpose.

The film thickness of the compound (the organic salt or the inorganic salt) represented by General Formula (2) described above is preferably 0.5 nm or more and 100 nm or less, more preferably 1 nm or more and 50 nm or less.

The compound (the organic salt or the inorganic salt) represented by General Formula (2) described above may or may not be uniformly distributed at the interface between the photoelectric conversion layer and the hole transport layer, and for example, may exist locally in a plurality of regions (having an island shape or the like). The compound may be distributed in the perovskite layer or the hole transport layer by reacting the perovskite compound with a hole-transporting material in the hole transport layer, which will be described later. That is, it is desired that a region where the compound (the organic salt or the inorganic salt) represented by General Formula (2) described above exists is present between the perovskite layer in which the compound (the organic salt or the inorganic salt) represented by General Formula (2) described above does not exist and the hole transport layer in which the organic salt and the inorganic salt do not exist.

### <Hole Transport Layer>

The hole transport layer is a layer that transports holes generated in the perovskite layer to a second electrode described later. Therefore, the hole transport layer is preferably arranged adjacent to the perovskite layer. If the electron transport layer is adjacent to the perovskite layer, the hole transport layer is preferably adjacent to the perovskite layer on a surface opposite to a surface adjacent to the electron transport layer of the perovskite layer. Further, if the film formed by the compound represented by General Formula (2) described above is provided on the perovskite layer, the hole transport layer is preferably arranged adjacent to the film.

The hole transport layer contains a solid hole-transporting material and if desired, other materials.

The solid hole-transporting material (may be simply referred to as the “hole-transporting material” hereinafter) is not particularly limited, as long as the material can transport holes, and can be appropriately selected according to a purpose. Examples of the solid hole-transporting material include, but are not limited to, organic compounds.

Examples of the organic compounds include, but are not limited to, polymer materials. Examples of the polymer materials include, but are not limited to, polythiophene compounds, polyphenylenevinylene compounds, polyfluorene compounds, polyphenylene compounds, polyarylamine compounds, and polythiadiazole compounds.

Examples of the polythiophene compound include, but are not limited to, compounds such as poly(3-n-hexylthiophene), poly(3-n-octyloxythiophene), poly(9,9′-dioctyl-fluorene-co-bithiophene), poly(3,3′″-didodecyl-quaterthiophene), poly(3,6-dioctylthieno[3,2-b]thiophene), poly(2,5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), or poly(3,6-dioctylthieno[3,2-b]thiophene-co-bithiophene).

Examples of the polyphenylene vinylene compounds include, but are not limited to, compounds such as poly[2-methoxy-5-(2-ethylhexyloxy)-1,4-phenylene vinylene], poly[2-methoxy-5-(3,7-dimethyloctyloxy)-1,4-phenylenevinylene], or poly[(2-methoxy-5-(2-ethylhexyloxy)-1,4-phenylenevinylene)-co-(4,4′-biphenylene-vinylene)].

Examples of the polyfluorene compounds include, but are not limited to, compounds such as poly(9,9′-didodecylfluorenyl-2,7-diyl), poly [(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], or poly[(9,9-dioctyl-2,7-diyl)-co-(1,4-(2,5-dihexyloxy)benzene)].

Examples of the polyphenylene compounds include, but are not limited to, compounds such as poly [2,5-dioctyloxy-1,4-phenylene] and poly[2,5-di(2-ethylhexyloxy-1,4-phenylene].

Examples of the polyarylamine compounds include, but are not limited to, compounds such as poly[(9,9-dioctylfluorenyl-2,7-diyl)-alt-co-(N,N′-diphenyl)-N,N′-di(p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly [phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], or poly[4-(2-ethylhexyloxy)phenylimino-1,4-biphenylene].

Examples of the polythiadiazole compounds include, but are not limited to, compounds such as poly[(9,9-dioctylfluorenyl-2,7-diyl)-alt-co-(1,4-benzo(2,1′,3)thiadiazole] or poly(3,4-didecylthiophene-co-(1,4-benzo(2,1′,3)thiadiazole).

Among these compounds, the polythiophene compounds and polyarylamine compounds are preferred in consideration of the carrier mobility and the ionization potential.

Examples of the hole-transporting material include, but are not limited to, compounds represented by General Formula (1) below.

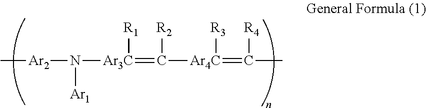

In General Formula (1) described above, Ar₁ represents an aromatic hydrocarbon group that may include a substituent, Ar₂ and Ar₃ each independently represent a divalent group of a monocyclic, non-fused polycyclic, or fused polycyclic aromatic hydrocarbon group that may include a substituent, Ar₄ represents a divalent group of benzene, thiophene, biphenyl, anthracene, or naphthalene that may include a substituent, R₁ to R₄ each independently represent a hydrogen atom, an alkyl group, or an aryl group, and n represents an integer of 2 or more.

The weight-average molecular weight of the polymer represented by General Formula (1) described above is an integer of 2,000 or more.

In General Formula (1) described above, Ar is an aromatic hydrocarbon group, and represents, for example, an aryl group.

Examples of the aryl group include, but are not limited to, a phenyl group, a 1-naphthyl group, and a 9-anthracenyl group. The aryl group may include a substituent. Examples of the substituent include, but are not limited to, an alkyl group, an alkoxy group, and an aryl group. Ar₂ and Ar₃ each independently represent a divalent group of a monocyclic, non-fused polycyclic, or fused polycyclic aromatic hydrocarbon group, and represent, for example, an arylene group or a divalent heterocyclic group. Examples of the arylene group include, but are not limited to, 1,4-phenylene, 1,1′-biphenylene, and 9,9′-di-n-hexylfluorene. An example of the divalent heterocyclic group includes, but is not limited to, 2,5-thiophene. The aryl group may include a substituent. Examples of the substituent include, but are not limited to, an alkyl group, an alkoxy group, and an aryl group.

Ar₄ represents a divalent group of benzene, thiophene, biphenyl, anthracene, or naphthalene, each of which may be substituted with a substituent. Examples of the substituent include, but are not limited to, an alkyl group, an alkoxy group, and an aryl group.

Examples of R₁ to R₄ each independently include, but are not limited to, a hydrogen atom, an alkyl group, and an aryl group. Examples of the alkyl group include, but are not limited to, a methyl group and an ethyl group. Examples of the aryl group include, but are not limited to, a phenyl group and a 2-naphthyl group. The alkyl group and the aryl group may include a substituent.

The compound represented by General Formula (1) described above is preferably a compound represented by General Formula (4) below.

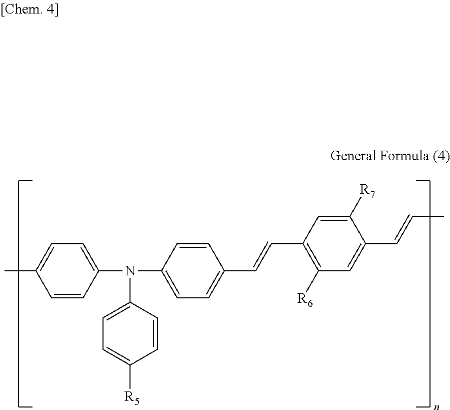

In General Formula (4) described above, R₅ represents a methyl group or a methoxy group, R₆ and R₇ represent an alkoxy group, and n represents an integer of 2 or more.

The weight-average molecular weight of the compound (polymer) represented by General Formula (1) described above is preferably 2,000 or more and 150,000 or less.

The weight-average molecular weight can be measured by gel permeation chromatography (GPC).

Examples of the compound represented by General Formula (1) described above include, but are not limited to, (A-1) to (A-22) below. Note that the compound represented by General Formula (1) is not limited to the compounds below.

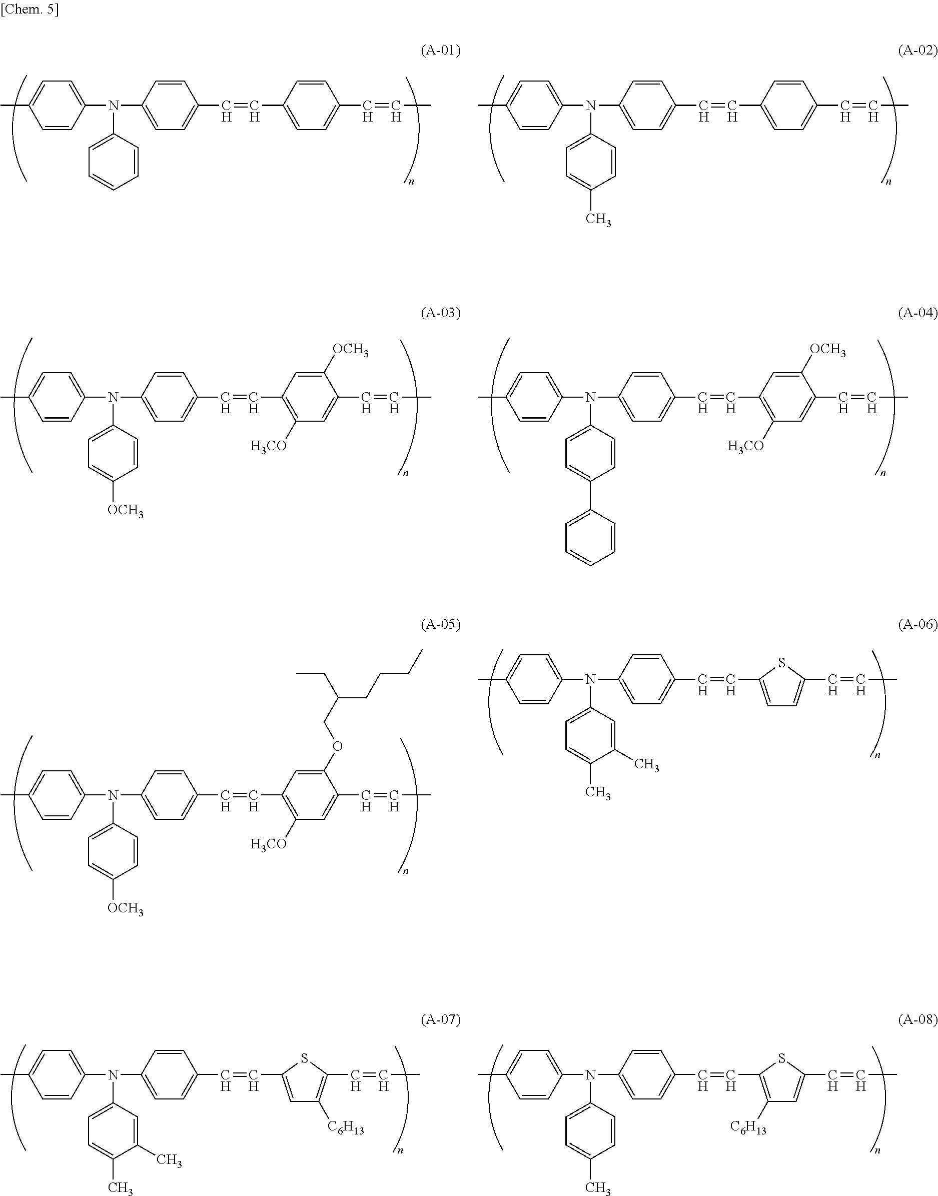

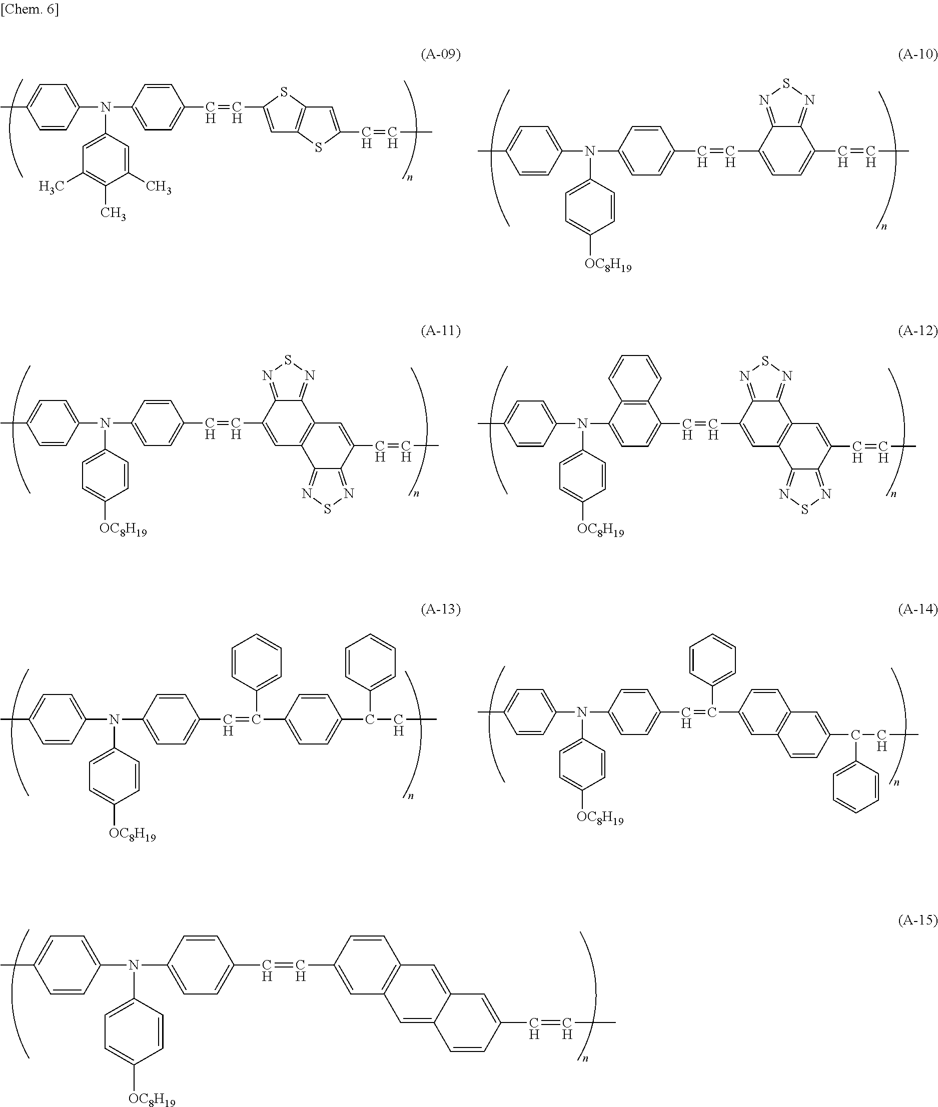

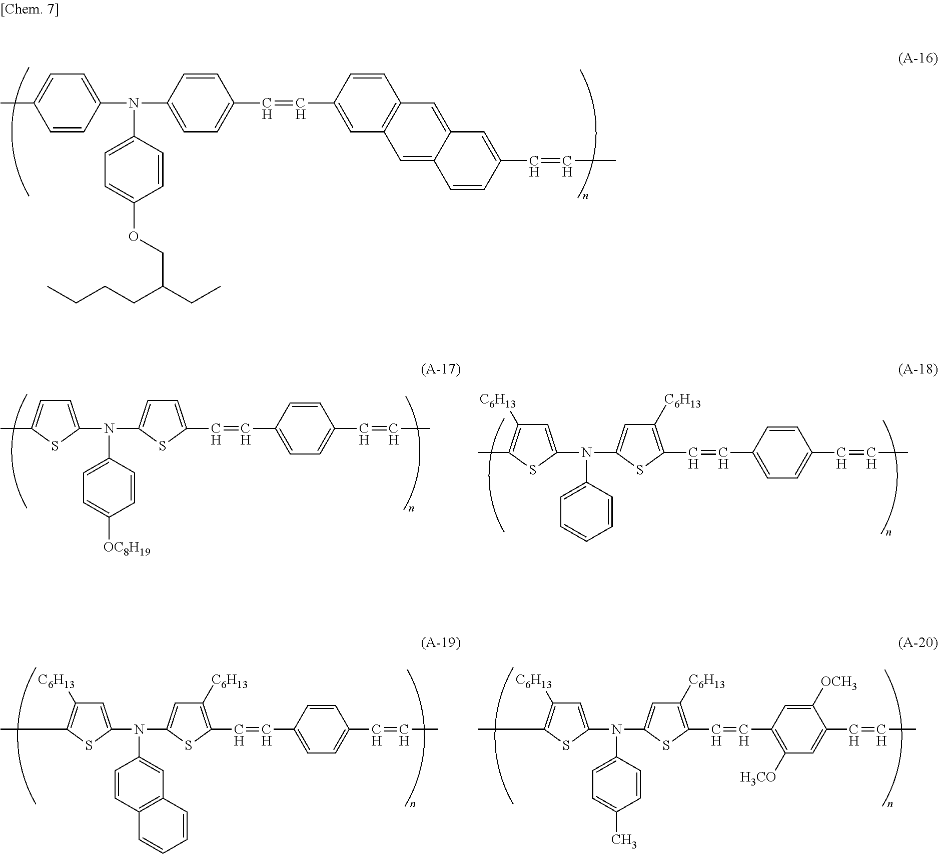

A compound represented by General Formula (5) may be further included in the compound represented by General Formula (1) described above.

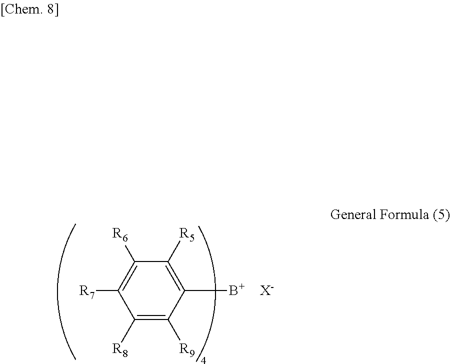

In General Formula (5) described above, R₅ to R₉ represent a hydrogen atom, a halogen atom, an alkyl group, an alkoxy group, or an aryl group, and may be the same or different. X represents a cation. R₅ and R₆, or R₆ and R₇ may together form a ring structure.

Examples of the halogen atom include, but are not limited to, a chlorine atom, a bromine atom, and an iodine atom.

Examples of the alkyl group include, but are not limited to, an alkyl group including 1 or more and 6 or less carbon atoms. The alkyl group may be substituted with a halogen atom. Examples of the alkoxy group include, but are not limited to, an alkoxy group including 1 or more and 6 or less carbon atoms.

Examples of the aryl group include, but are not limited to, a phenyl group.

The cation is not particularly limited and can be appropriately selected according to a purpose. Examples of the cation include, but are not limited to, alkali metal cations, phosphonium cations, iodonium cations, nitrogen-containing cations, and sulfonium cations. Here, the nitrogen-containing cation refers to an ion having a positive charge on a nitrogen atom. Examples of the nitrogen-containing cation include, but are not limited to, an ammonium cation, a pyridinium cation, and an imidazolium cation.

Specific examples of the compound represented by General Formula (5) described above include, but are not limited to, (B-01) to (B-28) below.

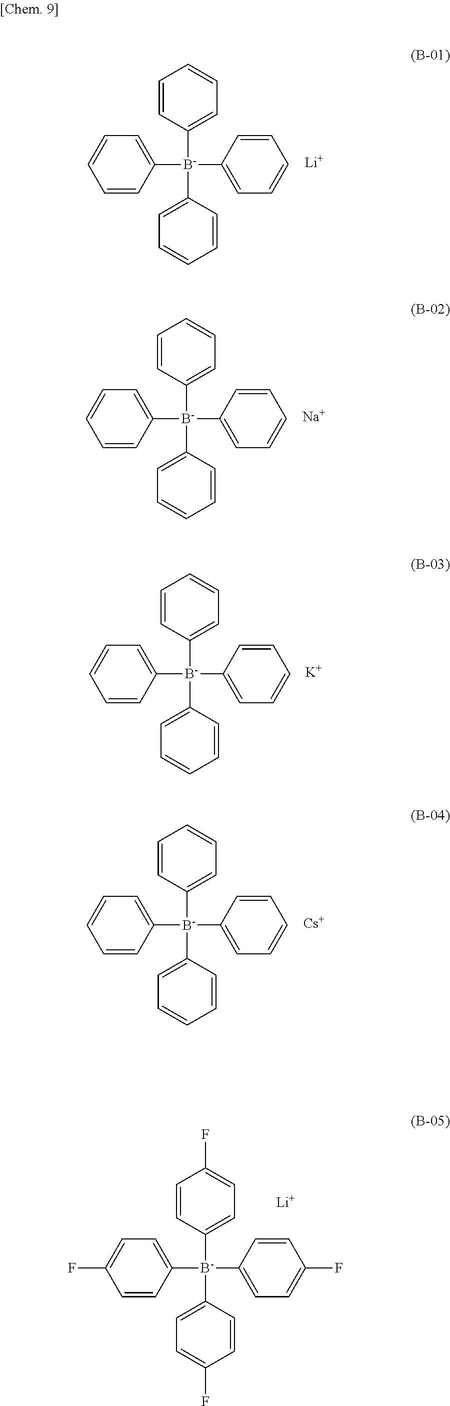

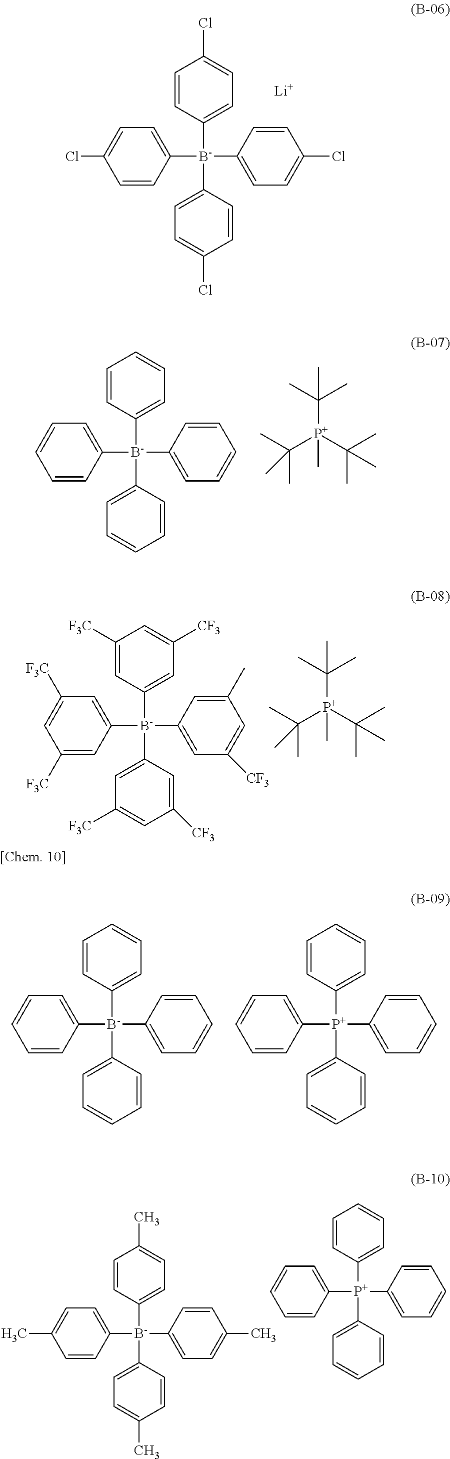

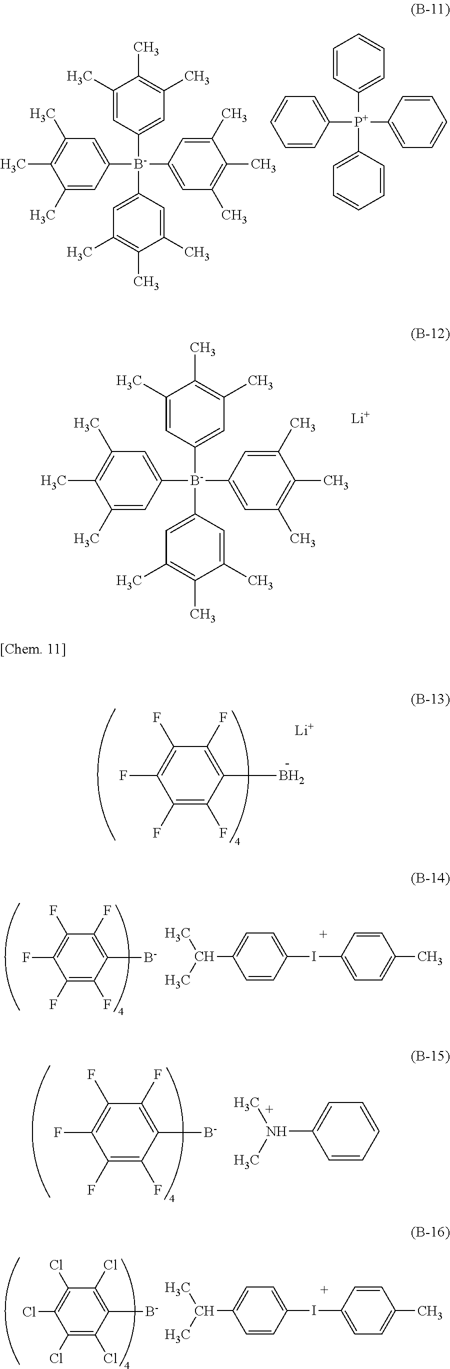

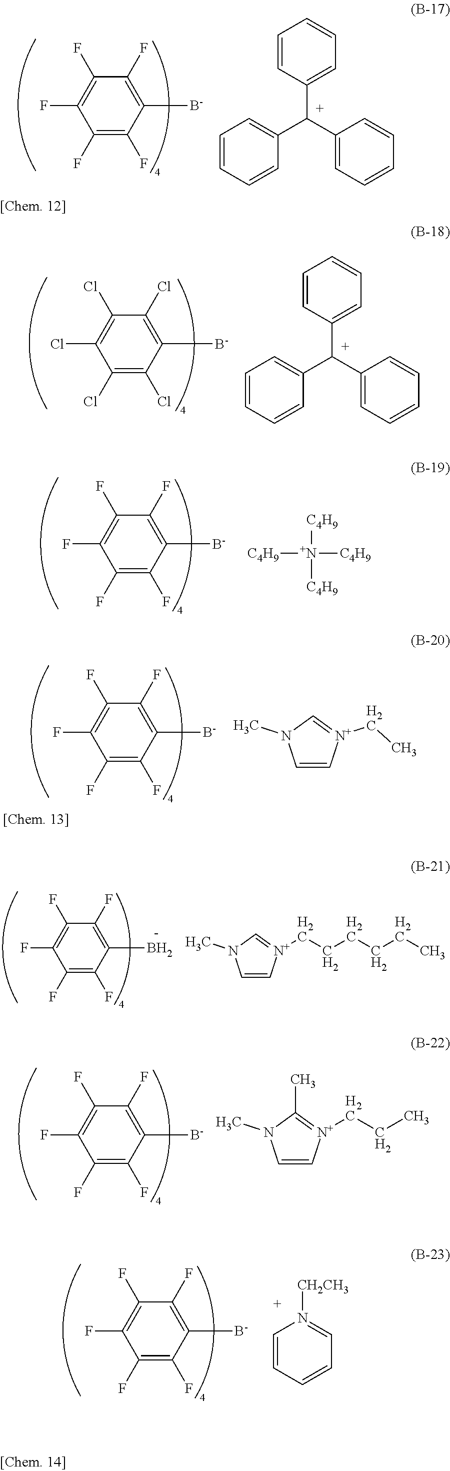

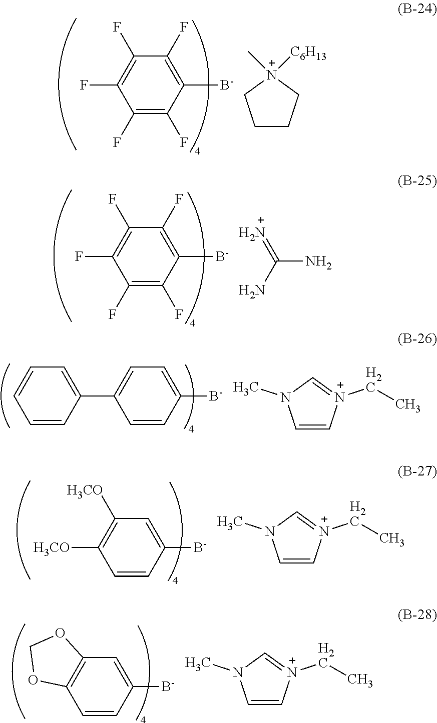

The mass ratio (A:B) of the compound (polymer) A represented by General Formula (1) described above and the compound B represented by General Formula (5) described above in the hole transport layer is not particularly limited, and can be appropriately selected according to a purpose. However, the mass ratio is preferably from 20:1 to 1:1, both inclusive, and more preferably from 10:1 to 1:1, both inclusive, from the viewpoint of the hole transfer. The average thickness of the hole transport layer is preferably 10 nm or more and 1000 nm or less, and more preferably 20 nm or more and 100 nm or less.

For example, the hole transport layer further contains another solid hole-transporting material, and if desired, other materials.

The other solid hole-transporting material (may simply be referred to as the “hole-transporting material” hereinafter) is not particularly limited, as long as the material can transport holes, and may be appropriately selected according to a purpose. However, the other solid hole-transporting material preferably contains an organic compound.

If an organic compound is used as the hole-transporting material, the hole transport layer contains, for example, a plurality of types of organic compounds.

The hole transport layer may contain a polymer compound as the organic compound. A polymer material used in the hole transport layer is not particularly limited and can be appropriately selected according to a purpose. Examples of the polymer material include, but are not limited to, polythiophene compounds, polyphenylenevinylene compounds, polyfluorene compounds, polyphenylene compounds, polyarylamine compounds, and polythiadiazole compounds.

Examples of the polythiophene compound include, but are not limited to, poly(3-n-hexylthiophene), poly(3-n-octyloxythiophene), poly(9,9′-dioctyl-fluorene-co-bithiophene), poly(3,3′″-didodecyl-quaterthiophene), poly(3,6-dioctylthieno[3,2-b]thiophene), poly(2,5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), or poly(3,6-dioctylthieno[3,2-b]thiophene-co-bithiophene).

Examples of the polyphenylene vinylene compounds include, but are not limited to, poly[2-methoxy-5-(2-ethylhexyloxy)-1,4-phenylene vinylene], poly[2-methoxy-5-(3,7-dimethyloctyloxy)-1,4-phenylenevinylene], or poly[(2-methoxy-5-(2-ethylhexyloxy)-1,4-phenylenevinylene)-co-(4,4′-biphenylene-vinylene)].

Examples of the polyfluorene compounds include, but are not limited to, poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], or poly[(9,9-dioctyl-2,7-diyl)-co-(1,4-(2,5-dihexyloxy)benzene)].

Examples of the polyphenylene compounds include, but are not limited to, poly[2,5-dioctyloxy-1,4-phenylene] and poly[2,5-di(2-ethylhexyloxy-1,4-phenylene].

Examples of the polyarylamine compounds include, but are not limited to, poly[(9,9-dioctylfluorenyl-2,7-diyl)-alt-co-(N,N′-diphenyl)-N,N′-di(p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly [phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene].

Examples of the polythiadiazole compounds include, but are not limited to, poly[(9,9-dioctylfluorenyl-2,7-diyl)-alt-co-(1,4-benzo(2,1′,3)thiadiazole and poly(3,4-didecylthiophene-co-(1,4-benzo(2,1′,3)thiadiazole).

Among these compounds, the polythiophene compounds and polyarylamine compounds are preferred in consideration of the carrier mobility and the ionization potential.

In addition to the polymers described above, the hole transport layer may also contain a low molecular weight compound alone or a mixture of a low molecular weight compound and a high molecular weight compound.

A chemical structure of the low molecular weight hole-transporting material is not particularly limited. Examples of the low molecular weight hole-transporting material include, but are not limited to, oxadiazole compounds, triphenylmethane compounds, pyrazoline compounds, hydrazone compounds, tetraarylbenzidine compounds, stilbene compounds, spirobifluorene compounds, and thiophene oligomers.

Examples of the oxadiazole compounds include, but are not limited to, oxadiazole compounds described in Japanese Examined Patent Application Publication No. S34-5466 and Japanese Unexamined Patent Application Publication No. S56-123544.

Examples of the triphenylmethane compounds include, but are not limited to, triphenylmethane compounds described in Japanese Examined Patent Application Publication No. S45-555.

Examples of the pyrazoline compounds include, but are not limited to, pyrazoline compounds described in Japanese Examined Patent Application Publication No. S52-4188.

Examples of the hydrazone compounds include, but are not limited to, hydrazone compounds described in Japanese Examined Patent Application Publication No. S55-42380.

Examples of the tetraarylbenzidine compounds include, but are not limited to, tetraarylbenzidine compounds described in Japanese Unexamined Patent Application Publication No. S54-58445.

Examples of the stilbene compounds include, but are not limited to, stilbene compounds described in Japanese Unexamined Patent Application Publication No. S58-65440 and Japanese Unexamined Patent Application Publication No. S60-98437.

Examples of the spirobifluorene compounds include, but are not limited to, spirobifluorene compounds described in Japanese Unexamined Patent Application Publication No. 2007-115665, Japanese Unexamined Patent Application Publication No. 2014-72327, Japanese Unexamined Patent Application Publication No. 2001-257012, WO2004/063283, WO2011/030450, WO2011/45321, WO2013/042699, and WO2013/121835.

Examples of the thiophene oligomers include, but are not limited to, thiophene oligomers described in Japanese Unexamined Patent Application Publication No. H2-250881 and Japanese Unexamined Patent Application Publication No. 2013-033868.

The other materials contained in the hole transport layer are not particularly limited and can be appropriately selected according to a purpose. Examples of the other materials include, but are not limited to, additives and oxidizing agents.

The additives are not particularly limited and can be appropriately selected according to a purpose. Examples of the additives include, but are not limited to, iodine; metal iodides such as lithium iodide, sodium iodide, potassium iodide, cesium iodide, calcium iodide, copper iodide, iron iodide, or silver iodide; quaternary ammonium salts such as tetraalkylammonium iodide or pyridinium iodide; metal bromides such as lithium bromide, sodium bromide, potassium bromide, cesium bromide, or calcium bromide; bromine salts of quaternary ammonium compounds such tetraalkylammonium bromide or pyridinium bromide; metal chlorides such as copper chloride or silver chloride; metal acetate salts such as copper acetate, silver acetate, or palladium acetate; metal sulfates such as copper sulfate or zinc sulfate; metal complexes such as ferrocyanide-ferricyanide or ferrocene-ferricinium ions; sulfur compounds such as sodium polysulfide or alkylthiol-alkyldisulfide; viologen dyes; hydroquinone; and basic compounds such as pyridine, 4-t-butylpyridine, or benzimidazole.

Additionally, an oxidizing agent can be added.

The type of the oxidizing agent is not particularly limited and can be appropriately selected according to a purpose. Examples of the types of the oxidizing agent include, but are not limited to, tris(4-bromophenyl)aminium hexachloroantimonate, silver hexafluoroantimonate, nitrosonium tetrafluoroborate, silver nitrate, and cobalt complexes. Note that the entire hole-transporting material may or may not be oxidized by the oxidizing agent, and an effect can be obtained as long as the hole-transporting material is partially oxidized. Moreover, the oxidizing agent may or may not be removed from the system after the reaction.

By including the oxidizing agent in the hole transport layer, a part or all of the hole-transporting material can be converted into radical cations, which makes it possible to improve conductivity and enhance the durability and the stability of the output characteristics.

The average thickness of the hole transport layer is not particularly limited and can be appropriately selected according to a purpose. However, on the perovskite layer, the average thickness of the hole transport layer is preferably 0.01 μm or more and 20 μm or less, more preferably 0.1 μm or more and 10 μm or less, and even more preferably 0.2 μm or more and 2 μm or less.

The hole transport layer can be formed directly on the perovskite layer. A method of manufacturing the hole transport layer is not particularly limited and can be appropriately selected according to a purpose. Examples of the method include, but are not limited to, a method of forming a thin film in a vacuum such as vacuum vapor deposition and a wet film-forming method. Among these methods, the wet film-forming method is particularly preferable, and the method of coating the perovskite layer is more preferable from the viewpoint of the manufacturing cost and the like.

The wet film-forming method is not particularly limited and can be appropriately selected according to a purpose. Examples of the wet film-forming method include, but are not limited to, a dip method, a spray method, a wire bar method, a spin coating method, a roller coating method, a blade coating method, and a gravure coating method. For example, methods such as letterpress, offset, gravure, intaglio, rubber plate, and screen printing may be used as the wet printing method.

The hole transport layer may be manufactured by film formation in a supercritical fluid or a subcritical fluid having a temperature and pressure lower than the critical point, for example. The supercritical fluid refers to a fluid that exists as a non-condensed high-density fluid in a temperature and pressure range exceeding the limit (critical point) where gas and liquid can coexist, does not condense even when being compressed, and is in a state at a critical temperature or higher and a critical pressure or higher. The supercritical fluid is not particularly limited and can be appropriately selected according to a purpose, but a supercritical fluid having a low critical temperature is preferable.

The subcritical fluid is not particularly limited, as long as the subcritical fluid exists as a high-pressure liquid in the temperature and pressure range near the critical point, and can be appropriately selected according to a purpose. Fluids mentioned as examples of supercritical fluids can also be suitably used as subcritical fluids.

Examples of the supercritical fluids include, but are not limited to, carbon monoxide, carbon dioxide, ammonia, nitrogen, water, alcohol solvents, hydrocarbon solvents, halogen solvents, and ether solvents.

Examples of the alcohol solvents include, but are not limited to, methanol, ethanol, and n-butanol.

Examples of the hydrocarbon solvents include, but are not limited to, ethane, propane, 2,3-dimethylbutane, benzene, and toluene. Examples of halogen solvents include, but are not limited to, methylene chloride and chlorotrifluoromethane.

An example of the ether solvents includes, but is not limited to, dimethyl ether. Each of these may be used alone or in combination with others.

Among these fluids, carbon dioxide has a critical pressure of 7.3 MPa and a critical temperature of 31° C., and thus, is preferable because the supercritical state can be easily achieved, and handling is easy because carbon dioxide is nonflammable.

The critical temperature and the critical pressure of the supercritical fluid are not particularly limited and can be appropriately selected according to a purpose. The critical temperature of the supercritical fluid is preferably −273° C. or higher and 300° C. or lower, and more preferably 0° C. or higher and 200° C. or lower.

In addition to the supercritical fluid and the subcritical fluid, an organic solvent and an entrainer can be used together. By adding an organic solvent and an entrainer, it is possible to adjust the solubility in the supercritical fluid more easily.

The organic solvent is not particularly limited and can be appropriately selected according to a purpose. Examples of the organic solvent include, but are not limited to, ketone solvents, ester solvents, ether solvents, amide solvents, halogenated hydrocarbon solvents, and hydrocarbon solvents.

Examples of the ketone solvents include, but are not limited to, acetone, methyl ethyl ketone, and methyl isobutyl ketone.

Examples of the ester solvents include, but are not limited to, ethyl formate, ethyl acetate, and n-butyl acetate.

Examples of the ether solvents include, but are not limited to, diisopropyl ether, dimethoxyethane, tetrahydrofuran, dioxolane, and dioxane.

Examples of the amide solvents include, but are not limited to, N,N-dimethylformamide, N,N-dimethylacetamide, and N-methyl-2-pyrrolidone.

Examples of the halogenated hydrocarbon solvents include, but are not limited to, dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvents include, but are not limited to, n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

Each of these may be used alone or in combination with others.

After laminating the hole-transporting material on the perovskite layer, a press treatment may be performed. By performing the press treatment, the hole-transporting material is brought into closer contact with the perovskite layer, so that the power generation efficiency may be improved.

A method of the press treatment is not particularly limited and can be appropriately selected according to a purpose. Examples of the method include, but are not limited to, a press molding method using a flat plate such as an infrared (IR spectroscopy) tablet molding device and a roll press method using a roller.

The pressure during the press treatment is preferably 10 kgf/cm² or more, and more preferably 30 kgf/cm² or more.

The duration of the press treatment is not particularly limited and can be appropriately selected according to a purpose, but is preferably 1 hour or less. Moreover, heat may be applied during the press treatment.

During the press treatment, a release agent may be sandwiched between a pressing device and an electrode.

The release agent is not particularly limited and can be appropriately selected according to a purpose. Examples of the release agent include, but are not limited to, fluoro resins such as polytetrafluoroethylene, polychlorotrifluoroethylene, tetrafluoroethylene hexafluoropropylene copolymer, perfluoroalkoxyfluoro resin, polyvinylidene fluoride, ethylene tetrafluoroethylene copolymer, ethylene chloro-trifluoroethylene copolymer, and polyvinyl fluoride. Each of these may be used alone or in combination with others.

After performing the press treatment and before providing the second electrode, a film containing a metal oxide may be provided between the hole transport layer and a second electrode.

The metal oxide is not particularly limited and can be appropriately selected according to a purpose. Examples of the metal oxide include, but are not limited to, molybdenum oxide, tungsten oxide, vanadium oxide, and nickel oxide. Each of these may be used alone or in combination with others. Among the metal oxides, molybdenum oxide is preferred.

A method of providing the film containing the metal oxide on the hole transport layer is not particularly limited and can be appropriately selected according to a purpose. Examples of the method include, but are not limited to, sputtering, a method of forming a thin film in a vacuum such as vacuum vapor deposition, and a wet film-forming method.

As the wet film-forming method of forming the film containing the metal oxide, a method of preparing a paste in which a powder or a sol of the metal oxide is dispersed, and then applying the paste onto the hole transport layer is preferable.

The wet film-forming method is not particularly limited and can be appropriately selected according to a purpose. Examples of the wet film-forming method include, but are not limited to, a dip method, a spray method, a wire bar method, a spin coating method, a roller coating method, a blade coating method, and a gravure coating method. For example, methods such as letterpress, offset, gravure, intaglio, rubber plate, and screen printing may be used as the wet printing method.

An average thickness of the film containing the metal oxide is not particularly limited and can be appropriately selected according to a purpose, but is preferably 0.1 nm or more and 50 nm or less, and more preferably 1 nm or more and 10 nm or less.

### <Second Electrode>

The photoelectric conversion element of the present embodiment includes a second electrode. The second electrode can be formed on the hole transport layer or on the metal oxide in the hole transport layer.

A material used in the second electrode may be similar to that of the first electrode.

Examples of the material of the second electrode include, but are not limited to, metals, carbon compounds, conductive metal oxides, and conductive polymers.

Examples of the metals include, but are not limited to, platinum, gold, silver, copper, and aluminum.

Examples of the carbon compounds include, but are not limited to, graphite, fullerene, carbon nanotubes, and graphene.

Examples of the conductive metal oxides include, but are not limited to, ITO, FTO, and ATO. Examples of the conductive polymers include, but are not limited to, polythiophene and polyaniline.

Each of these may be used alone or in combination with others.

The second electrode can be appropriately formed on the hole transport layer by a method such as coating, lamination, vapor deposition, CVD, and attaching depending on the type of material used and the type of the hole transport layer.

In the photoelectric conversion element of the present embodiment, it is preferable that at least one of the first electrode and the second electrode is substantially transparent.

It is preferable that the side of the first electrode is transparent and the incident light is incident from the side of the first electrode side. In this case, it is preferable to use a material that reflects light on the side of the second electrode, and a metal, glass on which a conductive oxide is deposited, plastic, or a metal thin film are preferably used.

It is also effective to provide an antireflection layer on the side of the incident light.

### <Electrode Protection Layer (Passivation Layer)>

The photoelectric conversion element of the present embodiment preferably includes the electrode protection layer (may be referred to as a passivation layer).

The electrode protection layer is a layer arranged between a sealing portion, which will be described later, and the second electrode.

The electrode protection layer is a layer that prevents the second electrode from being peeled off by the sealing portion.

The electrode protection layer is not particularly limited, as long as the electrode protection layer is arranged on a surface on the side of the second electrode where the sealing portion is provided, and may be arranged so that the second electrode is does not completely contact the sealing portion, or may be arranged so that the second electrode partially contacts the sealing portion, as long as the effect of the present embodiment can be achieved.

Examples of the material of the electrode protection layer include, but are not limited to, oxides and fluorine compounds.

An example of the oxides includes, but is not limited to, aluminum oxide.

Examples of the fluorine compounds include, but are not limited to, silicon nitride and silicon oxide. Among these materials, silicon oxide, which is a fluorine compound having a silane structure, is preferable as the fluorine compound.

The average thickness of the electrode protection layer is preferably 10 nm or more, and more preferably 50 nm or more.

### <Second Substrate>

The photoelectric conversion element of the present embodiment may include a second substrate.

The second substrate is not particularly limited, can be appropriately selected according to a purpose, and a material similar to that of the support body (the first substrate) may be used for the second substrate.

The second substrate is arranged to face the support body (the first substrate) to sandwich the perovskite layer.

A shape, a structure, and a size of the second substrate are not particularly limited, and can be appropriately selected according to a purpose.

The material of the second substrate is not particularly limited, can be appropriately selected according to a purpose, and can be, for example, a material similar to that of the support body (the first substrate).

The second substrate is not particularly limited, and well-known substrates can be used. Examples of the substrates include, but are not limited to, glass, plastic films, and ceramics. An uneven portion may be formed in a bonding portion between the second substrate and a sealing member to improve adhesion.

A method of forming the uneven portion is not particularly limited and can be appropriately selected according to a purpose. Examples of the method include, but are not limited to, sandblasting, waterblasting, abrasive paper, chemical etching, and laser processing.

As a means of improving the adhesion between the second substrate and the sealing member described later, for example, organic matter on the surface may be removed, or hydrophilicity may be improved. A means for removing the organic matter on the surface of the second substrate is not particularly limited and can be appropriately selected according to a purpose. Examples of the means include, but are not limited to, UV ozone cleaning and an oxygen plasma treatment.

The photoelectric conversion element of the present embodiment may include a sealing member.

### <Sealing Member>

In the photoelectric conversion element of the present embodiment, it is possible and effective to use a sealing member that shields at least the perovskite layer and the hole transport layer from the external environment of the photoelectric conversion element. In other words, in the present embodiment, it is preferable to further include a sealing member that shields the perovskite layer from the external environment of the photoelectric conversion element.

As the sealing member, a conventionally known member can be used, as long as the sealing member can reduce an excessive intrusion of moisture and oxygen from the external environment into the inside of the sealing portion. The sealing member also has the effect of preventing mechanical breakage due to pressure from the outside, and a conventionally known member can be used, as long as the effect can be realized.

The material of the sealing member is not particularly limited and can be appropriately selected according to a purpose. Examples of the material include, but are not limited to, cured acrylic resins and cured epoxy resins.

As the cured acrylic resins, any known material can be used, as long as the material is a cured monomer or oligomer including an acrylic group in the molecule.

As the cured epoxy resins, any known material can be used, as long as the material is a cured monomer or oligomer including an epoxy group in the molecule.

Examples of the types of the epoxy resin include, but are not limited to, water dispersion type, solvent-free type, solid type, heat curing type, curing agent mixed type, and ultraviolet curing type. Among the types of the epoxy resin, the heat curing type and the ultraviolet curing type are preferable, and the ultraviolet curing type is more preferable. Note that even the ultraviolet curing type epoxy resin can be heated, and it is preferable to perform heating even after ultraviolet curing.

Examples of the types of the epoxy resin include, but are not limited to, bisphenol A type, bisphenol F type, novolac type, cyclic aliphatic type, long chain aliphatic type, glycidylamine type, glycidyl ether type, and glycidyl ester type. Each of these may be used alone or in combination with others.

It is preferable to mix a curing agent and various types of additives with the epoxy resin, if desired.

The curing agent is not particularly limited and can be appropriately selected according to a purpose. Examples of the curing agent include, but are not limited to, amine-based curing agents, acid anhydride-based curing agents, polyamide-based curing agents, and other curing agents.

Examples of the amine-based curing agents include, but are not limited to, aliphatic polyamines such as diethylenetriamine and triethylenetetramine, and aromatic polyamines such as metaphenylenediamine, diaminodiphenylmethane, and diaminodiphenylsulfone. Examples of the acid anhydride-based curing agents include, but are not limited to, phthalic anhydride, tetra and hexahydrophthalic anhydride, methyltetrahydrophthalic anhydride, methylnadic anhydride, pyromellitic anhydride, het anhydride, and dodecenylsuccinic anhydride.

Examples of the other curing agents include, but are not limited to, imidazoles and polymercaptans. Each of these may be used alone or in combination with others.

The additive is not particularly limited and can be appropriately selected according to a purpose. Examples of the additive include, but are not limited to, fillers, gap agents, polymerization initiators, desiccants (moisture absorbents), curing accelerators, coupling agents, softening agents, colorants, auxiliary flame retardants, antioxidants, and organic solvents.

Among these additives, fillers, gap agents, curing accelerators, polymerization initiators, and desiccants (moisture absorbents) are preferable, and fillers and polymerization initiators are more preferable.

By including a filler as the additive, the infiltration of moisture and oxygen can be suppressed, and further, effects such as a reduction in volume shrinkage during curing, a reduction of the outgassing amount during curing or heating, an improvement of the mechanical strength, and control of thermal conductivity and fluidity can be obtained. Therefore, including a filler as the additive is very effective in maintaining a stable output in various environments.

Further, with regard to the output characteristics and durability of the photoelectric conversion element, in addition to the influence from the infiltration of moisture and oxygen, an influence from outgas generated during curing or heating of the sealing member is also to be considered. In particular, the outgas generated during heating has a great influence on the output characteristics of a photoelectric conversion element being stored in a high-temperature environment.

When being included in the sealing member, the filler, the gap agent, or the desiccant can suppress the infiltration of moisture and oxygen, and reduce the amount of the sealing member being used, and thus, it possible to achieve an effect of reducing outgassing.

Providing the sealing member with a filler, a gap agent, and a desiccant is effective during curing and also during storage of the photoelectric conversion element in a high-temperature environment.

The filler is not particularly limited and can be appropriately selected according to a purpose. Examples of the filler include, but are not limited to, inorganic fillers such as crystalline or amorphous silica, talc, alumina, aluminum nitride, silicon nitride, calcium silicate, and calcium carbonate. Each of these may be used alone or in combination with others.

An average particle diameter of primary particles in the filler is preferably 0.1 μm or more and 10 μm, and preferably 1 μm or more and 5 μm or less. When the average particle diameter of the primary particles in the filler is within the preferable range mentioned above, the effect of suppressing the infiltration of moisture and oxygen can be sufficiently obtained, the viscosity is appropriate, and the adhesion to the substrate and defoaming properties are improved. This preferable range is also effective for controlling a width of the sealing portion and for workability.

The content of the filler is preferably 10 parts by mass or more and 90 parts by mass or less, and more preferably 20 parts by mass or more and 70 parts by mass or less relative to the entire sealing member (100 parts by mass). When the content of the filler is within the preferable range mentioned above, the effect of suppressing the infiltration of moisture and oxygen is sufficiently obtained, the viscosity is appropriate, and the adhesion and workability are also excellent.

The gap agent is also called a gap controller or a spacer. By including a gap agent as an additive, it is possible to control a gap of the sealing portion. For example, if a sealing member is applied onto the first substrate or the first electrode, and the second substrate is placed above the first substrate or the first electrode to seal the first substrate or the first electrode, by mixing the sealing member with the gap agent, the gap of the sealing portion is aligned with the size of the gap agent, so that the gap of the sealing portion can be easily controlled.

The gap agent is not particularly limited and can be appropriately selected according to a purpose, as long as the gap agent is granular, has a uniform particle diameter, and has high solvent resistance and heat resistance. The gap agent preferably has high affinity with the epoxy resin and has a spherical particle shape. Specifically, glass beads, silica fine particles, organic resin fine particles, and the like are preferable. Each of these may be used alone or in combination with others.

The particle diameter of the gap agent can be selected according to a gap of the sealing portion to be set, and is preferably 1 μm or more and 100 μm or less, and more preferably 5 μm or more and 50 μm or less.

The polymerization initiator is not particularly limited, as long as the polymerization initiator initiates polymerization using heat or light, and can be appropriately selected according to a purpose. Examples of the polymerization initiator include, but are not limited to, thermal polymerization initiators and photopolymerization initiators.

The thermal polymerization initiator is a compound that generates active species such as radicals and cations by heat. Examples of the thermal polymerization initiator include, but are not limited to, azo compounds such as 2,2′-azobisbutyronitrile (AIBN) and peroxides such as benzoyl peroxide (BPO). Examples of a thermal cationic polymerization initiator include, but are not limited to, benzenesulfonic acid esters and alkylsulfonium salts.

A photo-cationic polymerization initiator is preferably used as the photopolymerization initiator in the case of an epoxy resin. When a photo-cationic polymerization initiator is mixed with an epoxy resin and irradiated with light, the photo-cationic polymerization initiator is decomposed and generates an acid. The acid causes the epoxy resin to polymerize and a curing reaction proceeds. The photo-cationic polymerization initiator provides effects such as low volume shrinkage during curing, no oxygen inhibition, and high storage stability.

Examples of the photo-cationic polymerization initiator include, but are not limited to, aromatic diazonium salts, aromatic iodonium salts, aromatic sulfonium salts, metacelone compounds, and silanol/aluminum complexes.

A photoacid generator having a function of generating an acid when being irradiated with light can also be used as the polymerization initiator. The photoacid generator acts as an acid that initiates cationic polymerization, and examples of the photoacid generator include, but are not limited to, onium salts such as ionic sulfonium salts and iodonium salts including a cationic part and an anionic part. Each of these may be used alone or in combination with others.

The added amount of the polymerization initiator may vary depending on the material being used, but is preferably 0.5 parts by mass or more and 10 parts by mass or less, and more preferably, 1 part by mass or more and 5 parts by mass or less, relative to the entire sealing member (100 parts by mass). By setting the added amount within the preferred range mentioned above, curing proceeds appropriately, the amount of residual uncured material can be reduced, and excessive outgassing can be prevented.

The desiccant, also referred to as a moisture absorbent, is a material that has a function of physically or chemically adsorbing moisture, and by including the desiccant in the sealing member, the moisture resistance can be further enhanced and the influence from outgassing can be reduced.

The desiccant is not particularly limited and can be appropriately selected according to a purpose, but is preferably in the form of particles. Examples of the desiccant include, but are not limited to, inorganic water-absorbent materials such as calcium oxide, barium oxide, magnesium oxide, magnesium sulfate, sodium sulfate, calcium chloride, silica gel, molecular sieves, and zeolites. Among the desiccants, zeolites having high moisture absorption are preferred. Each of these may be used alone or in combination with others.

The curing accelerator, also called a curing catalyst, is a material that accelerates the curing speed and is mainly used for thermosetting epoxy resins.

The curing accelerator is not particularly limited and can be appropriately selected according to a purpose. Examples of the curing accelerator include, but are not limited to, tertiary amines or tertiary amine salts such as 1,8-diazabicyclo(5,4,0)-undec-7-ene (DBU) and 1,5-diazabicyclo(4,3,0)-non-5-ene (DBN), imidazoles such as 1-cyanoethyl-2-ethyl-4-methylimidazole and 2-ethyl-4-methylimidazole, phosphines or phosphonium salts such as triphenylphosphine and tetraphenylphosphonium/tetraphenylborate.

Each of these may be used alone or in combination with others.

The coupling agent is not particularly limited and can be appropriately selected according to a purpose, as long as the coupling agent is formed of a material that has the effect of increasing the molecular bond strength. Examples of the coupling agent include, but are not limited to, silane coupling agents, and more specifically, silane coupling agents such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)3-aminopropylmethyldimethoxysilane, N-(2-aminoethyl)3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)3-aminopropyltrimethoxysilane hydrochloride, and 3-methacryloxypropyltrimethoxysilane. Each of these may be used alone or in combination with others.

As the sealing member, epoxy resin compositions commercially available as sealing materials, seal material, and adhesives are known, and can be effectively used in the present embodiment.

The epoxy resin compositions also include epoxy resin compositions developed and marketed for use in solar cells and organic EL devices, which can be used particularly effectively in the present embodiment. Commercially available epoxy resin compositions include, for example, TB3118, TB3114, TB3124, TB3125F (manufactured by ThreeBond Co., Ltd.), WORLD ROCK 5910, WORLD ROCK 5920, WORLD ROCK 8723 (manufactured by Kyoritsu Chemical Co., Ltd.), and WB90US (P) (manufactured by Moresco Co., Ltd.).

A sheet-like sealing material can also be used as the sealing portion.

The sheet-like sealing material is, for example, a sheet on which a sealing portion such as an epoxy resin is formed in advance. The sheet is formed of glass, a film having a high gas barrier property, or the like, and corresponds to the second substrate of the present embodiment, or a combination of the second substrate and a sealing base material.

The sealing base material and the second substrate can be formed in one process by attaching the sheet-like sealing material to the second electrode and then, pressing the sheet-like sealing material while heating.

It is also possible and effective to create a structure in which a hollow portion is provided according to a formation pattern of the sealing portion formed on the sheet.

If the sealing portion to be formed on the sheet is formed on the entire surface of the sheet, a “surface seal” is obtained. If the sealing portion is formed as a pattern so that the hollow portion is provided inside the photoelectric conversion element according to the formation pattern of the sealing portion, a “frame seal” can be obtained.

Examples of the sheet-like sealing material include, but are not limited to, an aluminum PET sheet with a rubber-based sealing portion (manufactured by Tesa, trade name: 61539), an aluminum PET sheet with an olefin-based sealing portion (manufactured by Moresco Co., Ltd., trade name: S2191), and an aluminum pet sheet with a sealing portion (manufactured by Ajinomoto Fine-Techno Co., Inc., trade name: FD21).

It is preferable that the sealing portion contains a moisture scavenger.

The moisture scavenger is not particularly limited and can be appropriately selected according to a purpose, as long as the material can scavenge moisture in a gas or a liquid. Examples of the moisture scavenger include, but are not limited to, water-absorbing materials and water-absorbing resins.

A moisture-capturing property measured for the moisture scavenger is preferably 20 mg/100 mm² or more, and more preferably 70 mg/100 mm² or more.

Examples of the water-absorbing material include, but are not limited to, desiccants.

Examples of the desiccants include, but are not limited to, activated carbon, zeolites, calcium compounds, magnesium compounds, silica gel, and organometallic compounds. As the desiccant, desiccants similar to those described as additives in the case where the epoxy resin is used as the adhesive layer material can also be used.

When the hollow portion is provided in the sealing portion, oxygen is contained in the hollow portion, so that the hole-transporting function of the hole transport layer can be stably maintained for a long period of time, which may be effective in improving the durability of the photoelectric conversion element.

In the present embodiment, the hollow portion preferably contains oxygen, and an oxygen concentration in the hollow portion is more preferably 10.0 vol % or more and 21.0 vol % or less.

The oxygen concentration in the hollow portion can be controlled by performing sealing (forming a sealing portion) in a glove box in which the oxygen concentration is adjusted. The oxygen concentration can be adjusted by a method using a gas cylinder having a specific oxygen concentration or a method using a nitrogen gas generator. The oxygen concentration in the glove box can be measured using a commercially available oxygen concentration meter or oxygen monitor.

For example, the oxygen concentration in the hollow portion formed by sealing can be measured by internal vapor analysis (IVA). Specifically, IVA is a method in which a photoelectric conversion element is placed in a high vacuum, a hole is formed in the photoelectric conversion element, and the generated gas and moisture is subjected to mass spectrometry. By using this method, the oxygen concentration contained in the hollow portion of the photoelectric conversion element can be clarified. The types of mass spectrometers include a quadrupole type and a time-of-flight type, the latter being used in more sensitive measurements.

A gas other than oxygen contained in the hollow portion is preferably an inert gas, such as nitrogen or argon.

When sealing is performed, it is preferable to control the dew point as well as the oxygen concentration in the glove box, which is effective in improving the output and durability. The dew point is defined as the temperature at which condensation begins when a gas containing water vapor is cooled.

The dew point is not particularly limited, but the dew point is preferably 0° C. or lower, and more preferably −20° C. or lower. A lower limit of the dew point is preferably −50° C. or higher.

A method of forming the sealing member is not particularly limited and can be appropriately selected according to a purpose. Examples of the method include, but are not limited to, a dispensing method, a wire bar method, a spin coating method, a roller coating method, a blade coating method, and a gravure coating method. For example, methods such as letterpress, offset, gravure, intaglio, rubber plate, and screen printing may be used as the method of forming the sealing member.

A passivation layer may be provided between the sealing member and the second electrode. The passivation layer is not particularly limited and can be appropriately selected according to a purpose, as long as the passivation layer is arranged so that the sealing member does not contact the second electrode. Examples of the passivation layer include, but are not limited to, aluminum oxide, silicon nitride, and silicon oxide.

### <Other Members>

Other members are not particularly limited and can be appropriately selected according to a purpose.

An embodiment for implementing the present embodiment will be described below with reference to the drawings. In each drawing, the same constituent components are denoted by the same reference numerals, and redundant explanation may be omitted.

### EMBODIMENT

An example of the photoelectric conversion element of the present embodiment will be described below with reference to the drawings. However, the present embodiment is not limited thereto. For example, the number, a position, a shape, and the like of the following constituent members, as well as items not described in the present embodiment, are also included in the scope of the present embodiment.

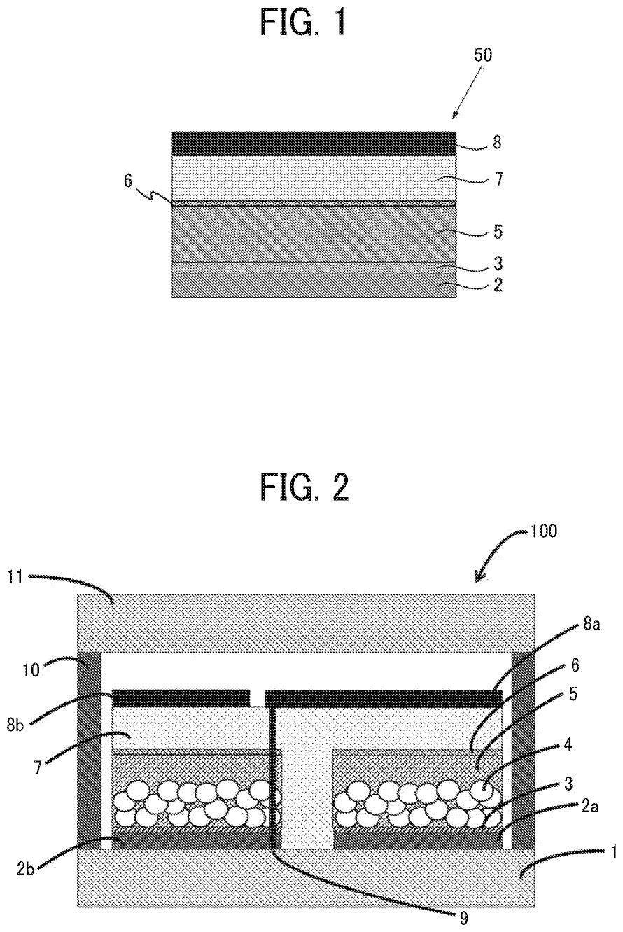

FIG. 1 is a schematic diagram of a solar cell as an embodiment of the photoelectric conversion element.

A solar cell 50 in FIG. 1 includes a first electrode (a support body) 2, a dense electron transport layer 3, a perovskite layer 5 as a photoelectric conversion layer, a hole transport layer 7, and a second electrode 8.

The first electrode 2 is in contact with the dense electron transport layer 3.

The dense electron transport layer 3 is in contact with the perovskite layer 5.

A film (layer) 6 containing a compound represented by General Formula (2) is provided between the perovskite layer 5 and the hole transport layer 7.

The hole transport layer 7 is in contact with the second electrode 8.

### (Photoelectric Conversion Module)

The photoelectric conversion module of the present embodiment includes a support body having flexibility, a perovskite layer, and a second electrode. The average thickness T₁ (μm) of the support body and the average thickness T₂ (nm) of the perovskite layer satisfy the following relationship T₂/T₁≤6. If desired, the photoelectric conversion module includes other layers.

Each layer may have a single-layer structure or a laminated structure.

In the photoelectric conversion module of the present embodiment, the support body, the perovskite layer, the second electrode, and the other layers are similar to those of the photoelectric conversion element of the present embodiment.

The photoelectric conversion module of the present embodiment preferably includes a photoelectric conversion element arrangement region where the photoelectric conversion elements of the present embodiment are arranged adjacently and connected in series or in parallel.

The photoelectric conversion module of the present embodiment is preferably a photoelectric conversion module including at least two adjacent photoelectric conversion elements, so that the support body (or the first electrode) in one of the photoelectric conversion elements and the second electrode in another one of the photoelectric conversion elements are electrically connected by a conductive portion passing through the photoelectric conversion layer.

The photoelectric conversion module may have a configuration including a pair of substrates and a photoelectric conversion element arrangement region where the photoelectric conversion elements are connected in series or in parallel between the pair of substrates, and the sealing member may be sandwiched between the pair of substrates.

### (Solar Cell Module)

The solar cell module of the present embodiment includes photoelectric conversion elements connected in series or in parallel. Each of the photoelectric conversion elements includes a support body having flexibility, a perovskite layer, and a second electrode.

The average thickness T₁ (μm) of the support body and the average thickness T₂ (nm) of the perovskite layer satisfy the following relationship T₂/T₁≤6. If desired, the solar cell module includes other layers.

The photoelectric conversion element in the solar cell module of the present embodiment is similar to the photoelectric conversion element of the present embodiment.

Note that connected in series or in parallel refers to an electrical connection.

### <Configuration of Solar Cell Module>

FIG. 2 is a cross-sectional view of a solar cell module of the present embodiment. As illustrated in FIG. 2, a solar cell module 100 includes, on a first substrate (support body) 1, a photoelectric conversion element including first electrodes 2a and 2b, the dense electron transport layer (dense layer) 3, a porous electron transport layer (porous layer) 4, the perovskite layer 5, a layer 6 of a compound represented by General Formula (2), a hole transport layer 7, and second electrodes 8a and 8b. In addition, the first electrodes 2 and 2b and the second electrodes 8a and 8b include a path conductively connected to an electrode extraction terminal.

In the solar cell module 100, a second substrate 11 is arranged to face the first substrate 1 to sandwich the photoelectric conversion element, and a sealing member 10 is arranged between the first substrate 1 and the second substrate 11.

In the solar cell module 100, the first electrodes 2a and 2b, the dense layer 3, the porous layer 4, and the perovskite layer 5 in a photoelectric conversion element a including the first electrode 2a and the second electrode 8a and a photoelectric conversion element b including the first electrode 2b and the second electrode 8b are separated by the hole transport layer 7, which is a continuous layer extending between the photoelectric conversion element a and the photoelectric conversion element b.

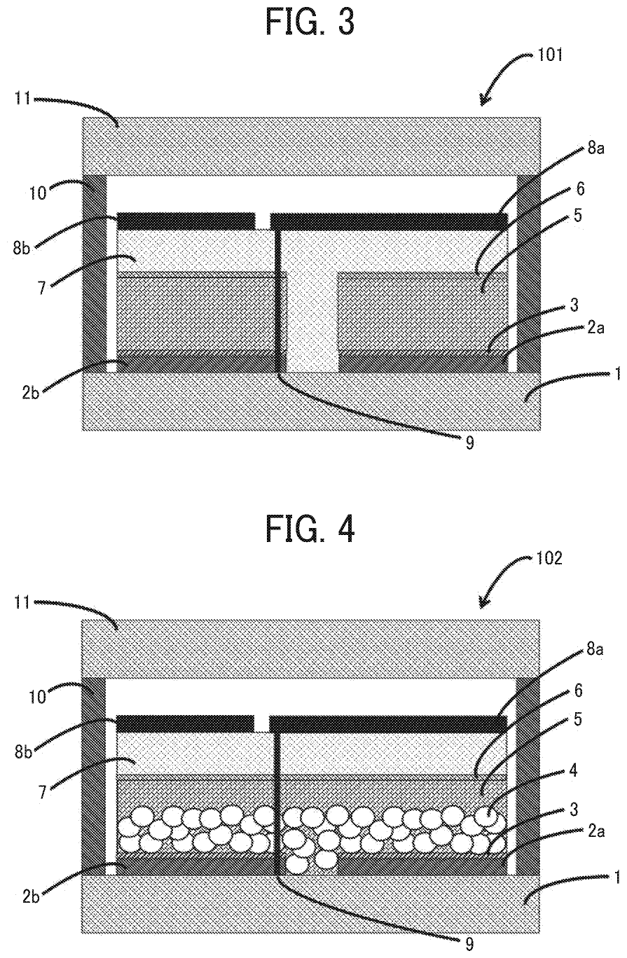

FIG. 3 is a cross-sectional view of a solar cell module of the present embodiment. As illustrated in FIG. 3, a solar cell module 101 includes, on the first substrate (support body) 1, a photoelectric conversion element including the first electrodes 2a and 2b, the dense electron transport layer (dense layer) 3, the perovskite layer 5, the layer 6 of the compound represented by General Formula (2), the hole transport layer 7, and the second electrodes 8a and 8b. In addition, the first electrodes 2a and 2b and the second electrodes 8a and 8b include a path conductively connected to an electrode extraction terminal.

In the solar cell module 101, the second substrate 11 is arranged to face the first substrate 1 to sandwich the photoelectric conversion element, and the sealing member 10 is arranged between the first substrate 1 and the second substrate 11.

In the solar cell module 101, the first electrodes 2a and 2b, the dense layer 3, and the perovskite layer 5 in the photoelectric conversion element a including the first electrode 2a and the second electrode 8a and the photoelectric conversion element b including the first electrode 2b and the second electrode 8b are separated by the hole transport layer 7, which is a continuous layer extending between the photoelectric conversion element a and the photoelectric conversion element b.

FIG. 4 is a cross-sectional view of a solar cell module of the present embodiment. As illustrated in FIG. 4, a solar cell module 102 includes, on the first substrate (support body) 1, a photoelectric conversion element including the first electrodes 2a and 2b, the dense electron transport layer (dense layer) 3, the porous electron transport layer (porous layer) 4, the perovskite layer 5, the layer 6 of the compound represented by General Formula (2), the hole transport layer 7, and the second electrodes 8a and 8b. In addition, the first electrodes 2a and 2b and the second electrodes 8a and 8b include a path conductively connected to an electrode extraction terminal.

In the solar cell module 102, the second substrate 11 is arranged to face the first substrate 1 to sandwich the photoelectric conversion element, and the sealing member 10 is arranged between the first substrate 1 and the second substrate 11.

In the solar cell module 102, the first electrodes 2a and 2b and the dense layer 3 in the photoelectric conversion element a including the first electrode 2a and the second electrode 8a and the photoelectric conversion element b including the first electrode 2b and the second electrode 8b are separated by the porous layer 4, the perovskite layer 5, and the hole transport layer 7, which are continuous layers extending between the photoelectric conversion element a and the photoelectric conversion element b.

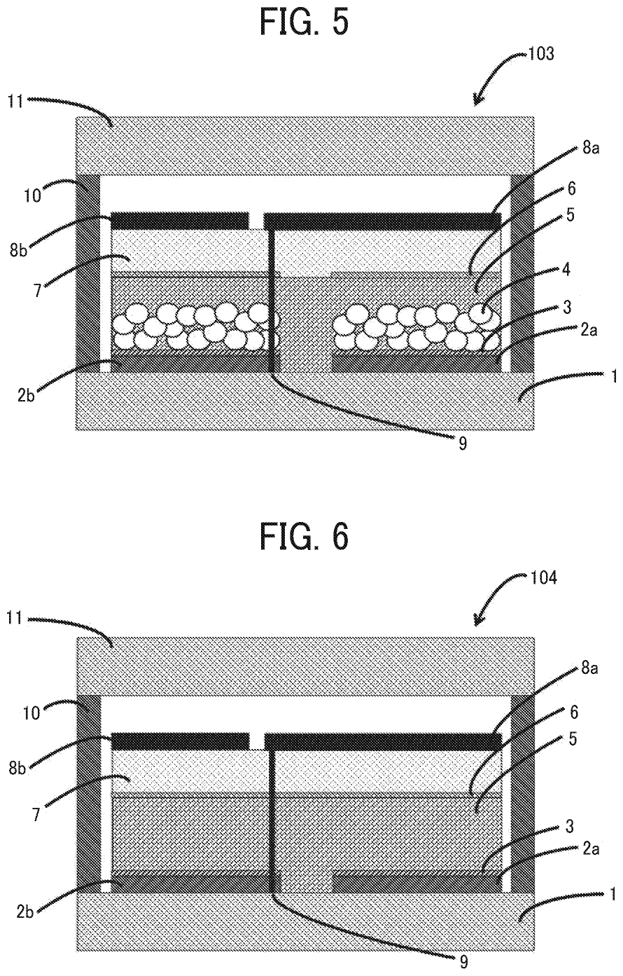

FIG. 5 is a cross-sectional view of a solar cell module of the present embodiment. As illustrated in FIG. 5, a solar cell module 103 includes, on the first substrate (support body) 1, a photoelectric conversion element including the first electrodes 2a and 2b, the dense electron transport layer (dense layer) 3, the porous electron transport layer (porous layer) 4, the perovskite layer 5, the layer 6 of the compound represented by General Formula (2), the hole transport layer 7, and the second electrodes 8a and 8b. In addition, the first electrodes 2a and 2b and the second electrodes 8a and 8b include a path conductively connected to an electrode extraction terminal.

In the solar cell module 103, the second substrate 11 is arranged to face the first substrate 1 to sandwich the photoelectric conversion element, and the sealing member 10 is arranged between the first substrate 1 and the second substrate 11.

In the solar cell module 103, the first electrodes 2a and 2b, the dense layer 3, and the porous layer 4 in the photoelectric conversion element a including the first electrode 2a and the second electrode 8a and the photoelectric conversion element b including the first electrode 2b and the second electrode 8b are separated by the perovskite layer 5 and the hole transport layer 7, which are continuous layers extending between the photoelectric conversion element a and the photoelectric conversion element b.

FIG. 6 is a cross-sectional view of a solar cell module of the present embodiment. As illustrated in FIG. 6, a solar cell module 104 includes, on the first substrate (support body) 1, a photoelectric conversion element including the first electrodes 2a and 2b, the dense electron transport layer (dense layer) 3, the perovskite layer 5, the layer 6 of the compound represented by General Formula (2), the hole transport layer 7, and the second electrodes 8a and 8b. In addition, the first electrodes 2a and 2b and the second electrodes 8a and 8b include a path conductively connected to an electrode extraction terminal.

In the solar cell module 104, the second substrate 11 is arranged to face the first substrate 1 to sandwich the photoelectric conversion element, and the sealing member 10 is arranged between the first substrate 1 and the second substrate 11.

In the solar cell module 104, the first electrodes 2a and 2b and the dense layer 3 in the photoelectric conversion element a including the first electrode 2a and the second electrode 8a and the photoelectric conversion element b including the first electrode 2b and the second electrode 8b are separated by the perovskite layer 5 and the hole transport layer 7, which are continuous layers extending between the photoelectric conversion element a and the photoelectric conversion element b.

The solar cell modules 100 to 104 are sealed by the first substrate 1, the sealing member 10, and the second substrate 11. Therefore, it is possible to control the water content and the oxygen concentration in a hollow portion existing between the second electrodes 8a and 8b and the second substrate 11. By controlling the water content and the oxygen concentration in the hollow portion of the solar cell modules 100 to 104, the power generation performance and the durability can be improved. That is, the solar cell module further includes the second substrate arranged to face the first substrate to sandwich the photoelectric conversion element and the sealing member that is arranged between the first substrate and the second substrate and seals the photoelectric conversion element, and thus, it is possible to control the water content and the oxygen concentration in the hollow portion, and therefore, the power generation performance and the durability can be improved.

The oxygen concentration in the hollow portion is not particularly limited and can be appropriately selected according to a purpose. However, the oxygen concentration is preferably 0% or more and 21% or less, more preferably 0.05% or more and 10% or less, and even more preferably 0.1% or more and 5% or less.

In the solar cell modules 100 to 104, the second electrodes 8a and 8b and the second substrate 11 are not in contact with each other, and thus, peeling and breakage of the second electrodes 8a and 8b can be prevented.

The solar cell modules 100 to 104 include a through portion 9 that electrically connects the photoelectric conversion element a and the photoelectric conversion element b. In the solar cell modules 100 to 104, the second electrode 8a of the photoelectric conversion element a and the first electrode 2b of the photoelectric conversion element b are electrically connected by a through portion 9 penetrating the hole transport layer 7, so that the photoelectric conversion element a and the photoelectric conversion element b are connected in series. By thus connecting a plurality of photoelectric conversion elements in series, the open-circuit voltage of the solar cell module can be increased.

The through portion 9 may penetrate the first electrode 2b and extend to the first substrate 1, or the forming of the through portion 9 may be stopped inside the first electrode 2b and the through portion 9 may not extend to the first substrate 1. In a case where the shape of the through portion 9 is a fine hole that penetrates the first electrode 2b and extends to the first substrate 1, if a total opening area of the fine hole is too large with respect to an area of the through portion 9, a cross-sectional film area of the first electrode 2b decreases, resulting in an increase in the resistance value, which may cause a decline in the photoelectric conversion efficiency. Therefore, the ratio of the total opening area of the fine hole relative to the area of the through portion 9 is preferably 5/100 or more and 60/100 or less.

A method of forming the through portion 9 is not particularly limited and can be appropriately selected according to a purpose. Examples of the method include, but are not limited to, sandblasting, waterblasting, chemical etching, laser processing, and abrasive paper. Among these methods, laser processing is preferable because fine holes can be formed without using sand, etching, resist, or the like, and processing can be performed in a clean manner and with good reproducibility. One of the reasons why laser processing is preferable is that, when the through portion 9 is formed, at least one of the dense layer 3, the porous layer 4, the perovskite layer 5, the layer 6 of the compound represented by General Formula (2), the hole transport layer 7, and the second electrode 8a can be removed by impact separation in the laser processing. Thus, a mask may or may not be provided during lamination, and the removal of the material used to form the photoelectric conversion element and the formation of the through portion can be performed collectively and easily.

Here, the perovskite layer in the photoelectric conversion element a and the perovskite layer in the photoelectric conversion element b may extend continuously or may be separated, and if the perovskite layers are separated, the distance is preferably 1 μm or more and 100 μm or less, and more preferably 5 μm or more and 50 μm or less. If the distance between the perovskite layer in the photoelectric conversion element a and the perovskite layer in the photoelectric conversion element b is 1 μm or more and 100 μm or less, the porous titanium oxide layer and the perovskite layer are cut, and the re-bonding of electrons due to diffusion decreases, so that it is possible to maintain power generation efficiency even after a prolonged exposure to light having high intensity. That is, in at least two photoelectric conversion elements adjacent to each other, if the distance between the electron transport layer and the perovskite layer in one photoelectric conversion element and the electron transport layer and the perovskite layer in another photoelectric conversion element is 1 μm or more and 100 μm or less, it is possible to maintain the power generation efficiency even after a prolonged exposure to light having high intensity.

Note that the distance between the electron transport layer and the perovskite layer in one photoelectric conversion element and the electron transport layer and the perovskite layer in another photoelectric conversion element in at least two photoelectric conversion elements adjacent to each other refers to the shortest distance among distances between outer peripheral portions (end portions) of the electron transport layer and the perovskite layer in each of the photoelectric conversion elements.

The solar cell module of the present embodiment can be applied to a power supply device by being combining with a circuit board and the like that controls a current being generated. Devices that utilize a power supply device include, but are not limited to, electronic desktop calculators and wristwatches. Moreover, a power supply device including the photoelectric conversion element of the present embodiment can also be applied to mobile phones, electronic notebooks, and electronic paper. A power supply device including the photoelectric conversion element of the present embodiment can also be used as an auxiliary power supply for extending the continuous usage time of a rechargeable or dry cell type electric appliance, and as a power supply that can be utilized even at night or the like by being combined with a secondary battery and the like. A power supply device including the photoelectric conversion element of the present embodiment can also be used in IoT devices, artificial satellites, and the like as a self-sustaining power source of which a battery may not be replaced and a power supply wiring may not be provided.

### (Electronic Device)

An electronic device of the present embodiment includes at least any one of the photoelectric conversion element and the photoelectric conversion module of the present embodiment, and a device that operates on electric power generated by photoelectric conversion by the at least any one of the photoelectric conversion element and the photoelectric conversion module, and if desired, also includes other devices.

The electronic device of the present embodiment includes at least any one of the photoelectric conversion element and the photoelectric conversion module of the present embodiment, a storage battery that stores electric power generated by photoelectric conversion by at the least any one of the photoelectric conversion element and the photoelectric conversion module, and a device that operates on the electric power stored in the storage battery, and if desired, may also include other devices.

### (Power Supply Module)

The power supply module includes at least any one of the photoelectric conversion element and the photoelectric conversion module of the present embodiment, and a power supply integrated circuit (power supply IC), and if desired, also includes other devices.

A specific embodiment of an electronic device including the photoelectric conversion element and the photoelectric conversion module of the present embodiment, and a device that operates on electric power obtained by the generation of electric power by the photoelectric conversion element and the photoelectric conversion module will be described.

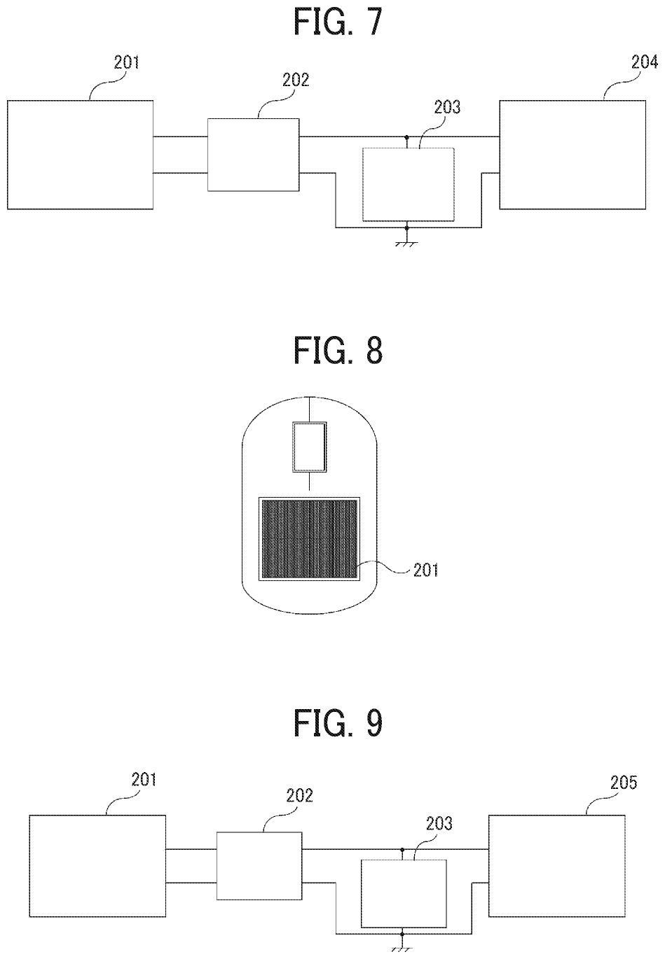

FIG. 7 illustrates an example using a mouse as the electronic device.

As illustrated in FIG. 7, a photoelectric conversion element 201, a photoelectric conversion module, a power supply IC 202, and further, a power storage device 203 are combined, and the supplied electric power is connected to a power supply of a control circuit 204 of the mouse. Thus, the power storage device 203 can be charged when the mouse is not in use, the electric power can be used to operate the mouse, and it is possible to obtain a mouse that may not be provided with wiring and of which a battery may not be replaced. A battery may not be provided, which is effective because a reduction in weight is also possible.

FIG. 8 illustrates a schematic diagram in which the photoelectric conversion element 201 is mounted in a mouse. The photoelectric conversion element 201, the power supply IC 202, and the power storage device 203 are mounted inside the mouse. However, an upper portion of the photoelectric conversion element 201 is covered with a transparent casing to expose the photoelectric conversion element 201 to light. It is also possible to form the entire casing of the mouse with a transparent resin. The arrangement of the photoelectric conversion element 201 is not limited to the present arrangement, and for example, it is possible to arrange the photoelectric conversion element 201 at a position where light is emitted even when the mouse is covered with a hand, which may be preferable.

Another embodiment of an electronic device including the photoelectric conversion element and the photoelectric conversion module of the present embodiment, and a device that operates on electric power obtained by the generation of electric power by the photoelectric conversion element and the photoelectric conversion module will be described.

FIG. 9 illustrates an example using a keyboard used in a personal computer as the electronic device.

As illustrated in FIG. 9, the photoelectric conversion element 201, the power supply IC 202, and the power storage device 203 are combined, and the supplied electric power is connected to a power supply of a control circuit 205 of the keyboard. Thus, the power storage device 203 can be charged when the keyboard is not in use, the electric power can be used to operate the keyboard, and it is possible to obtain a keyboard that may not be provided with wiring and of which a battery may not be replaced. A battery may not be provided, which is effective because a reduction in weight is also possible.

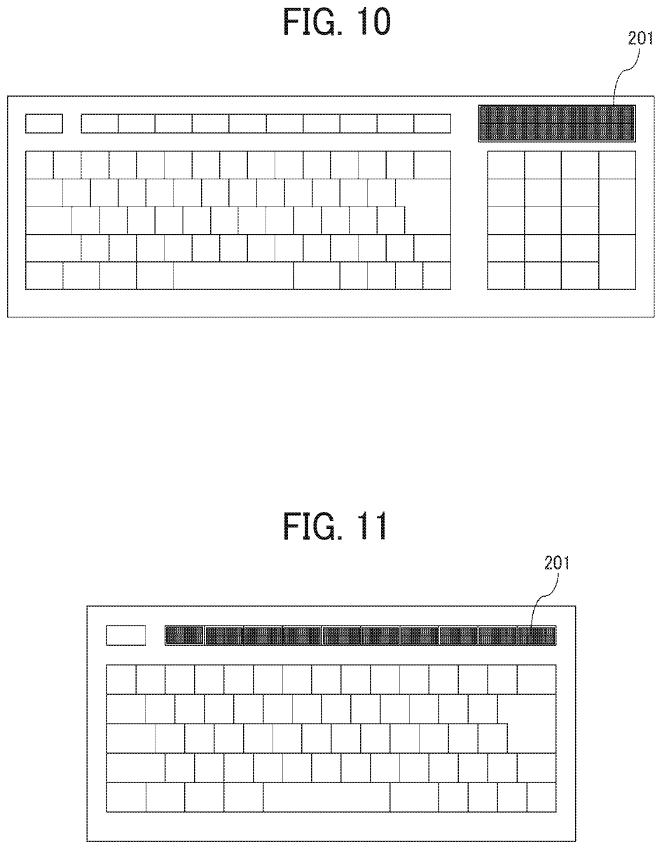

FIG. 10 illustrates a schematic diagram in which the photoelectric conversion element 201 is mounted in a keyboard. The photoelectric conversion element 201, the power supply IC 202, and the power storage device 203 are mounted inside the keyboard. However, an upper portion of the photoelectric conversion element 201 is covered with a transparent casing to expose the photoelectric conversion element 201 to light. It is also possible to form the entire casing of the keyboard with a transparent resin. The arrangement of the photoelectric conversion element 201 is not limited to the present arrangement.

In the case of a small keyboard in which a space for inserting the photoelectric conversion element is small, it is possible and effective to embed a small photoelectric conversion element in a part of keys as illustrated in FIG. 11.

Another embodiment of an electronic device including the photoelectric conversion element and the photoelectric conversion module of the present embodiment, and a device that operates on electric power obtained by the generation of electric power by the photoelectric conversion element and the photoelectric conversion module will be described.

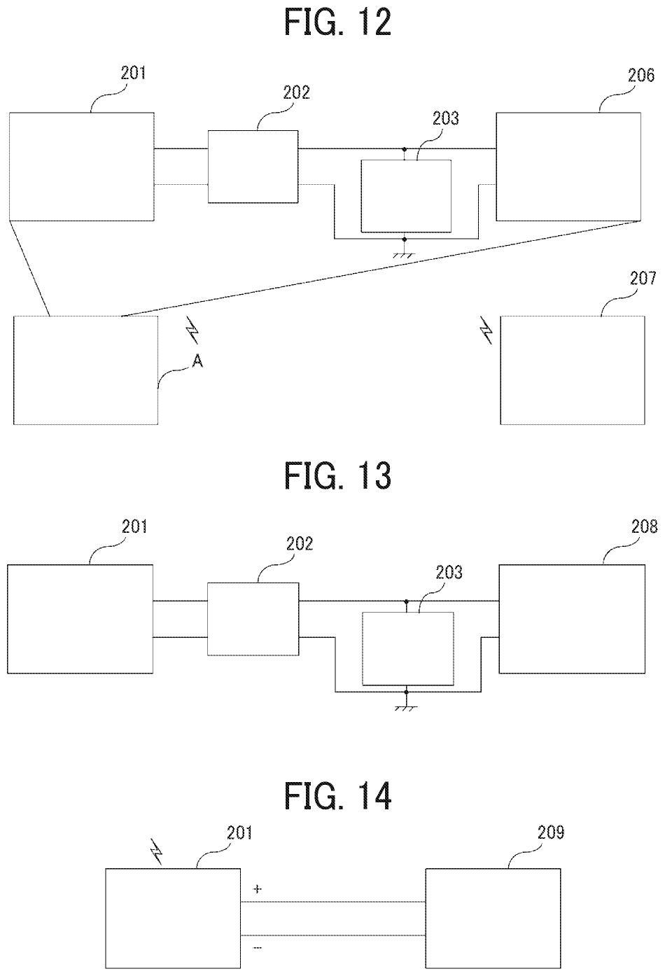

FIG. 12 illustrates an example using a sensor as the electronic device.

As illustrated in FIG. 12, the photoelectric conversion element 201, the power supply IC 202, and the power storage device 203 are combined, and the supplied electric power is connected to a power supply of a sensor circuit 206. Thus, it is possible to configure a sensor module A that may not be connected to an external power supply and of which a battery may not be replaced. The sensor module A may be applied to and may be effective in various sensors for sensing, for example, temperature and humidity, illuminance, human motion, CO₂ concentration, acceleration, UV intensity, noise, geomagnetism, or atmospheric pressure. As illustrated in FIG. 12, the sensor module periodically senses a measuring target and transmits read data to a device 207 such as a PC or a smartphone by radio communication.

With the development of IoT technologies, the use of sensors is expected to increase. Replacing the batteries of these numerous sensors one by one is time-intensive and laborious, and thus, is not practical. In addition, a sensor may be positioned in a location where battery replacement is difficult, such as on a ceiling and a wall, which also impairs operability. It is highly advantageous that power can be supplied by the photoelectric conversion element. Another advantage is that the photoelectric conversion element of the present embodiment provides a high output even under low illuminance, the output has little dependency on an incident angle of the light, and thus, the photoelectric conversion element provides a high degree of freedom in installation.

Another embodiment of an electronic device including the photoelectric conversion element and the photoelectric conversion module of the present embodiment, and a device that operates on electric power obtained by the generation of electric power by the photoelectric conversion element and the photoelectric conversion module will be described.

FIG. 13 illustrates an example using a turntable as the electronic device.

As illustrated in FIG. 13, the photoelectric conversion element 201, the power supply IC 202, and the power storage device 203 are combined, and the supplied electric power is connected to a power supply of a turntable control circuit 208. Thus, it is possible to configure a turntable that may not be connected to an external power supply and of which a battery may not be replaced.

For example, the turntable is used as a showcase for displaying goods, where it is not desired that the power supply wiring is visually recognizable. Also, at the time of battery replacement, it is desirable that the displayed goods are removed, which is work-intensive. The use of the photoelectric conversion element of the present embodiment can solve such problems and is effective.

### <Applications>

An electronic device including the photoelectric conversion element and the photoelectric conversion module of the present embodiment, and a device that operates on electric power obtained by the generation of electric power by the photoelectric conversion element and the photoelectric conversion module, as well as a power supply module have been described above. However, these are examples of some applications, and the applications of the photoelectric conversion element or the photoelectric conversion module of the present embodiment are not limited thereto.

The photoelectric conversion element and the photoelectric conversion module can be applied to a power supply device by being combined with a circuit board or the like that controls the generated current.

Examples of devices that utilize power supply devices include, but are not limited to, electronic desktop calculators, wristwatches, mobile phones, electronic notebooks, and electronic paper.

A power supply device including a photoelectric conversion element can also be used as an auxiliary power supply for extending the continuous usage time of a rechargeable or dry cell type electric appliance.

The photoelectric conversion element and the photoelectric conversion module of the present embodiment can function as a self-sustaining power source and can operate a device by using electric power generated by photoelectric conversion.

The photoelectric conversion element and the photoelectric conversion module of the present embodiment can generate electric power when being irradiated with light, and therefore, the electronic device may not be connected to a power supply and a battery may not be replaced. Therefore, it is possible to operate the electronic device even in a location where there is no power supply facility, attach the electronic device to a body to carry the electronic device, or operate the electronic device without replacing a battery in a location where battery replacement is difficult. If a dry cell is used, the electronic device may be heavier or larger in size, which may hinder installation of the electronic device on a wall or ceiling, or carrying the electronic device. On the other hand, the photoelectric conversion element and the photoelectric conversion module of the present embodiment have low weight and are thin, and thus, provide a high degree of freedom in installation and are highly advantageous when attached to the body and carried.

As described above, the photoelectric conversion element and the photoelectric conversion module of the present embodiment can be used as self-sustaining power sources and can be combined with various electronic devices. For example, the photoelectric conversion element and the photoelectric conversion module can be used in combination with a large number of electronic devices, such as a display device including an electronic desktop calculator, a wristwatch, a mobile phone, an electronic notebook, and electronic paper, an auxiliary device of a personal computer such as a mouse and a keyboard, various types of sensor devices such as a temperature/humidity sensor and a human motion sensor, transmitters such as a beacon and GPS, an auxiliary light, and a remote control.

The photoelectric conversion element and the photoelectric conversion module of the present application can maintain high output even after being bent, and thus, can also be used in flexible devices.

The photoelectric conversion element and the photoelectric conversion module of the present embodiment can generate power even with light having low illuminance, which enables power generation both indoors and in shade, providing a wide range of applications. In the photoelectric conversion element and the photoelectric conversion module of the present embodiment, there is no liquid leakage as in the case of a dry battery, and no risk of accidental ingestion as in the case of a button battery, and therefore, the photoelectric conversion element and the photoelectric conversion module offer a high degree of safety. Moreover, the photoelectric conversion element and the photoelectric conversion module can also be used as an auxiliary power supply for extending the continuous usage time of a rechargeable or dry cell type electric appliance. By combining the photoelectric conversion element and the photoelectric conversion module of the present embodiment with a device that operates on electric power generated by photoelectric conversion by the photoelectric conversion element and the photoelectric conversion module, it is possible to design an electronic device that has low weight, is easy to use, has a high degree of freedom in installation, reduces replacement work, is excellent in safety, and is also effective in reducing an environmental burden.

FIG. 14 is a general configuration diagram of an electronic device in which the photoelectric conversion element and/or the photoelectric conversion module of the present embodiment is combined with a device that operates on electric power generated by photoelectric conversion by the photoelectric conversion element and the photoelectric conversion module. Thus, power can be generated when the photoelectric conversion element is irradiated with light, and electric power can be extracted. The circuit of the device can be operated by the electric power.

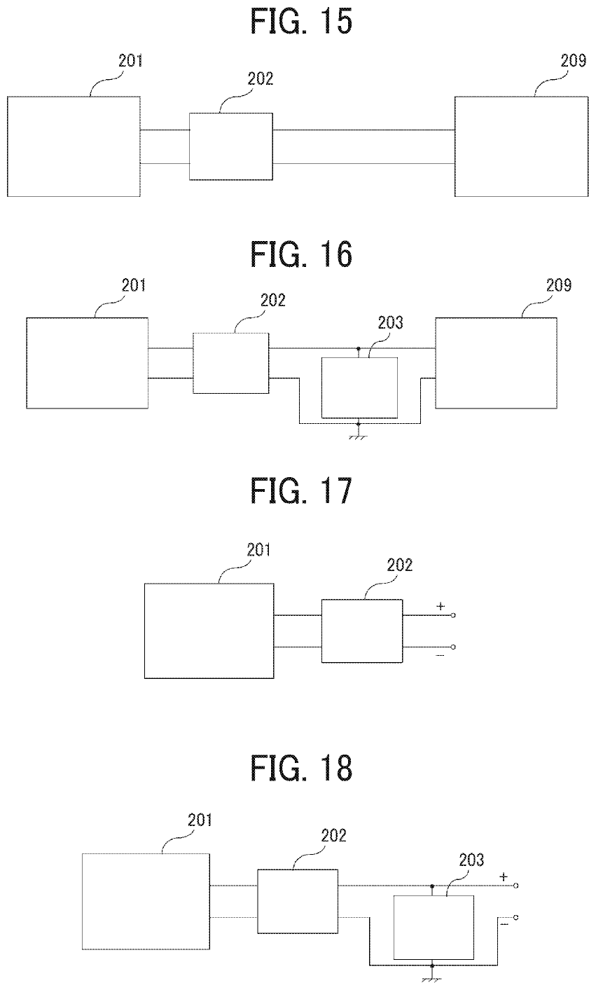

However, the output of the photoelectric conversion element fluctuates depending on the ambient illuminance, and thus, the electronic device illustrated in FIG. 14 may not operate in a stable manner. In this case, as illustrated in FIG. 15, to stably supply a voltage to the circuit, it is possible and effective to insert the power supply IC 202 for the photoelectric conversion element between the photoelectric conversion element 201 and a device circuit 209. Although the photoelectric conversion element can generate power when being irradiated with light of sufficient illuminance, if the illuminance for generating electric power is insufficient, it is not possible to generate a desired power, which is also a drawback of the photoelectric conversion element. In this case, as illustrated in FIG. 16, the power storage device 203 such as a capacitor can be mounted between the power supply IC 202 and the device circuit 209 to make it possible to charge the power storage device 203 with surplus power from the photoelectric conversion element 201. Thus, power stored in the power storage device 203 can be supplied to the device circuit 209 for a stable operation of the photoelectric conversion element 201, even in a case where the illuminance is too low or no light reaches the photoelectric conversion element 201.

When the electronic device in which the photoelectric conversion element and/or the photoelectric conversion module of the present embodiment is combined with the device circuit is further combined with the power supply IC and the power storage device, the electronic device can operate even in an environment without power supply and can be stably driven without battery replacement, and thus, it is possible to fully utilize the advantages of the photoelectric conversion element.

It is also possible and useful to use the photoelectric conversion element and/or the photoelectric conversion module of the present embodiment as a power supply module. For example, as illustrated in FIG. 17, by connecting the photoelectric conversion element and/or the photoelectric conversion module of the present embodiment to the power supply IC 202 for the photoelectric conversion element, it is possible to configure a direct-current power supply module that can supply power generated by photoelectric conversion by the photoelectric conversion element 201 at a constant voltage level via the power supply IC 202. Further, as illustrated in FIG. 18, by adding the power storage device 203 to the power supply IC 202, it is possible to charge the power storage device 203 with the power generated by the photoelectric conversion element 201. Thus, it is possible to configure a power supply module that supplies power even in a state where the illuminance is too low or no light reaches the photoelectric conversion element 201.

The power supply modules of the present embodiment illustrated in FIGS. 17 and 18 can be used as power supply modules in which a battery is not replaced, unlike in conventional primary batteries.

### EXAMPLES

Examples according to the present embodiment will be described below, but the present embodiment is in no way limited to these examples.

### <Synthesis of Hole-Transporting Material (A-05)>

A 100 ml four-necked flask was filled with 0.66 g (2.0 mmol) of a dialdehyde compound and 1.02 g (2.0 mmol) of diphosphonate illustrated in the figure below, nitrogen purging was performed, and 75 ml of tetrahydrofuran were added.

6.75 ml (6.75 mmol) of a 1.0 mol/dm³ tetrahydrofuran solution of potassium t-butoxide were added dropwise to the solution, stirred at room temperature for 2 hours, and then, diethyl benzylphosphonate and benzaldehyde were sequentially added and the solution was further stirred for 2 hours.

About 1 ml of acetic acid was added to terminate the reaction, and the solution was washed with water.

After removing the solvent by distillation under reduced pressure, the residue was purified by reprecipitation using tetrahydrofuran and methanol to obtain 0.95 g of a polymer compound (A-05).

The polystyrene-equivalent number-average molecular weight and weight-average molecular weight measured by gel permeation chromatography (GPC) were 8,500 and 20,000, respectively.

The ionization potential measured by using a photoelectron spectrometer AC-2 manufactured by Riken Keiki Co., Ltd. was 5.20 eV.

All ionization potentials mentioned below are values measured by using the AC-2.

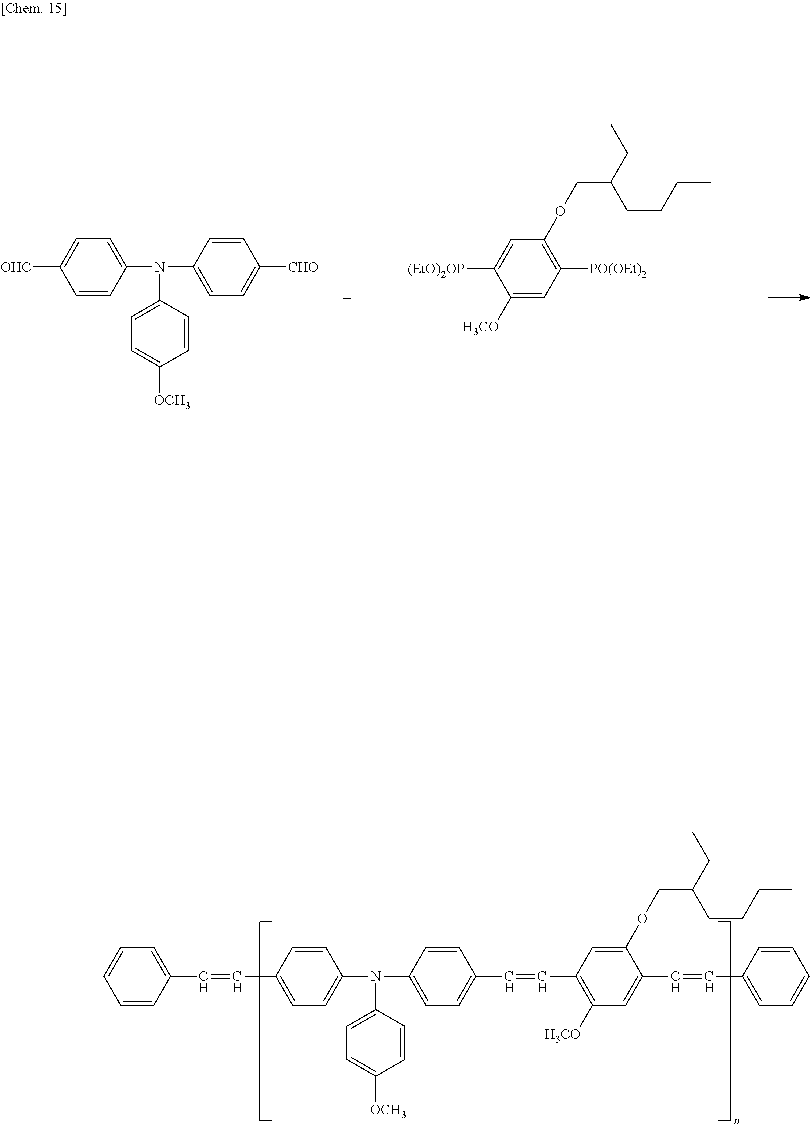

### Example 1

### <Manufacturing of Solar Cell Module>

First, a solution obtained by dissolving 0.36 g of a titanium diisopropoxide bis(acetylacetone) isopropyl alcohol solution (75%) in 10 ml of isopropyl alcohol was applied by using a spin coating method on an SUS (304) substrate (austenitic stainless steel, iron alloyed with about 18% of chromium and about 8% of nickel, substrate film thickness 50 μm) as a support body (first substrate) that also serves as the first electrode. Next, the obtained product was dried for 3 minutes at 120° C., and then baked for 30 minutes at 450° C., to prepare a dense electron transport layer (dense layer). The dense layer was prepared to have an average thickness from 10 nm to 40 nm.

Next, lead (II) iodide (0.5306 g), lead (II) bromide (0.0736 g), methylamine bromide (0.0224 g), and formamidine iodide (0.1876 g were added to N,N-dimethylformamide (0.8 ml) and dimethylsulfoxide (0.2 ml). 40 μL of a cesium iodide DMSO solution adjusted to 1.5 M was added to the obtained solution. The solution was heated and stirred at 60° C. and then applied onto the electron transport layer (porous layer) by using a spin coating method, while chlorobenzene (0.3 ml) was added to form a perovskite film. Afterwards, the formed perovskite film was dried at 150° C. for 30 minutes to manufacture the perovskite layer. The perovskite layer was formed to have an average thickness of 300 nm.

Further, a solution of 1 mM isopropyl alcohol in which 2-phenylethylammonium bromide was dissolved was applied to the formed perovskite layer by a spin coating method.

In Table 1 below, methylammonium is indicated as “MA” and formamidinium is indicated as “FA” in the composition of the perovskite layer.

Next, 73.6 mg of a synthesized hole-transporting material represented by (A-05) and 7.4 mg of an additive represented by (B-14) as an additive were weighed and dissolved in 3.0 ml of chlorobenzene.

The obtained solution was applied to the perovskite layer by using a spin coating method to prepare a hole transport layer.

The hole transport layer was prepared to have an average thickness (a portion on the perovskite layer) from 50 nm to 120 nm.

Further, a silver nanowire (manufactured by Sigma-Aldrich, 60 nm diameter×10 μm length in long direction, 0.5% isopropyl alcohol liquid dispersion) was applied as a transparent electrode on the hole transport layer so that an average thickness of the silver nanowire was 100 nm.

Next, a fluorine compound having a silane structure (product name: DURASURF DS-5935F130, manufactured by Harves Co., Ltd.) was formed as an electrode protection layer on the second electrode by die coating so that the average thickness was 10 nm.

An aluminum pet sheet including a sealing portion (manufactured by Tesa, pressure-sensitive adhesive A, peel strength: 5 N/l cm or more, desiccant: calcium oxide) in which the sealing portion, a sealing base material, and a second substrate are integrated was attached to an entire surface of a first substrate by using a vacuum attaching device (manufactured by JOYO ENGINEERING CO., LTD., device name: Air bag type vacuum laminator). The obtained product was pressure-bonded while being heating to 70° C. by a heating laminator to manufacture a photoelectric conversion module formed with the sealing portion, the sealing base material, and the second substrate.

Next, light was emitted onto an obtained solar cell module 1 from a solar simulator (AM 1.5, 100 mW/cm²) by using a solar cell evaluation system (manufactured by NF Circuit Design Block Co., Ltd., product name: As-510-PV03), and at the same time, the IV characteristics were measured to evaluate the solar cell characteristics (initial characteristics).

Next, after conducting a bending test under the following conditions, the solar cell characteristics (post-test characteristics) were evaluated again under conditions similar to the measurement conditions of the initial characteristics, and the maintenance rate (maintenance rate 1) of the conversion efficiency was calculated. Table 1 presents the results.

### <Bending Test Conditions>

DMLHB, a small desktop durability tester manufactured by Yuasa System Co., Ltd., was used, the second electrode side of the solar cell module was set to be a valley, and then, the bending test was conducted at a bending diameter of 30 mm, a bending speed of 60 r/min, and the number of times of bending as 100.

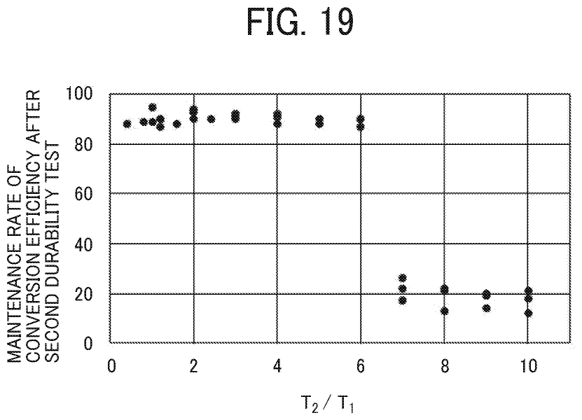

Subsequently, after the bending test, the solar cell module 1 was subjected to a test at high temperature and high humidity conducted at 60° C. and 90% RH to evaluate the influence of cracks. The solar cell characteristics were evaluated under conditions similar to the ones described above, and the maintenance rate (maintenance rate 2) of the conversion efficiency was calculated. Table 1 and FIG. 19 illustrate the results.

The test at high temperature and high humidity was performed by placing the solar cell module 1 in a constant temperature bath set to a temperature of 60° C. and a relative humidity of 90% for 100 hours.

### Examples 2 to 6

Solar cell modules 2 to 6 were manufactured similarly to Example 1, except that in Example 1, the conditions in the spin coating were changed, and the thickness of the perovskite layer was changed so that the ratio (T₂/T₁) of the average thickness T₁ (μm) of the support body and the average thickness T₂ (nm) of the perovskite layer gives values described in Table 1. The evaluation was performed similarly to Example 1.

### Examples 7 to 18

Solar cell modules 7 to 18 were manufactured similarly to Example 1, except that in Example 1, the support body was changed to materials described in Table 1, the conditions in the spin coating were changed, and the thickness of the perovskite layer was changed so that the ratio (T₂/T₁) of the average thickness T₁ (μm) of the support body and the average thickness T₂ (nm) of the perovskite layer gives values described in Table 1. The evaluation was performed similarly to Example 1.

### Examples 19 to 24

Solar cell modules 19 to 24 were manufactured similarly to Example 1, except that in Example 1, the composition of the perovskite layer was changed and the electron transport layer was changed to SnO₂, and the support body was changed to materials described in Table 1. The evaluation was performed similarly to Example 1.

### Examples 25 to 27

Solar cell modules 25 to 27 were manufactured similarly to Example 1, except that in Example 1, the composition of the perovskite layer was changed, and the support body was changed to materials described in Table 1. The evaluation was performed similarly to Example 1.

### Examples 28 to 31

Solar cell modules 28 to 31 were manufactured similarly to Example 1, except that in Example 1, the composition of the perovskite layer was changed, the material of the electron transport layer was changed, and the support body was changed to materials described in Table 1. The evaluation was performed similarly to Example 1. In addition, the porous layer was prepared as described below.

Next, a liquid dispersion of a titanium oxide paste (manufactured by Great Cell Solar, Co., Ltd., trade name: MPT-20) diluted with α-terpineol was applied to the dense layer by using a spin coating method, followed by drying at 120° C. for 3 minutes, and then baking at 550° C. for 30 minutes.

Subsequently, a solution of lithium bis(trifluoromethanesulfonyl)imide (manufactured by Kanto Chemical Co., Inc., product number: 38103) and dissolved acetonitrile 0.1 M (M refers to mol/dm³) was applied to the above-described film by using a spin coating method. The coated film was baked at 450° C. for 30 minutes to prepare a porous electron transport layer (porous layer). The porous layer was prepared to have an average thickness of 150 nm.

### Comparative Examples 1 to 4

Solar cell modules 32 to 35 were manufactured similarly to Example 1, except that in Example 1, the conditions in the spin coating were changed, and the thickness of the perovskite layer was changed so that the ratio (T₂/T₁) of the average thickness T₁ (μm) of the support body and the average thickness T₂ (nm) of the perovskite layer gives values described in Table 2. The evaluation was performed similarly to Example 1.

### Comparative Examples 5 to 13

Solar cell modules 36 to 44 were manufactured similarly to Example 1, except that in Example 1, the support body was changed to materials described in Table 2. The evaluation was performed similarly to Example 1.

TABLE 1

| | | <General | | | | Evaluation results | | | | | |
|---|---|---|---|---|---|---|---|---|---|---|---|
| | | Formula 1> | | | | | | | | | (After test at |
| | | Average | | | | | | | | | high |
| | | thickness of | | | | | | | | | temperature |
| | | perovskite | | | | | | | | | and high |
| | | T₂ (nm)/ | | | | | | | | (After bending | humidity) |
| | | average | Perovskite layer | | | | | | | test) | Maintenance |
| | | thickness of | <X_{α}Y_{β}M_{γ}> | | | | | | | Maintenance | rate after |
| | | support | X: Halogen | Electron | | | | | | rate after first | second |
| | | body T₁ | Y: Alkylamine | transport | Support | Voc | Jsc | | PCE | durability test | durability test |
| | | (μm) | M: Metal | layer | body | (V) | (mA/cm²) | FF | (%) | (%) | (%) |
| Examples | 1 | 6 | CsFAMAPbIBr | TiO₂ | SUS (50 | 1.03 | 22.5 | 0.72 | 16.69 | 82 | 90 |
| | | | | | μm) | | | | | | |
| | 2 | 5 | CsFAMAPbIBr | TiO₂ | SUS (50 | 1.06 | 18.8 | 0.73 | 14.51 | 83 | 88 |
| | | | | | μm) | | | | | | |
| | 3 | 4 | CsFAMAPbIBr | TiO₂ | SUS (50 | 1.1 | 12.5 | 0.7 | 9.76 | 87 | 92 |
| | | | | | μm) | | | | | | |
| | 4 | 3 | CsFAMAPbIBr | TiO₂ | SUS (50 | 1.08 | 6.25 | 0.72 | 4.86 | 90 | 91 |
| | | | | | μm) | | | | | | |
| | 5 | 2 | CsFAMAPbIBr | TiO₂ | SUS (50 | 1.07 | 2.08 | 0.7 | 1.56 | 88 | 90 |
| | | | | | μm) | | | | | | |
| | 6 | 1 | CsFAMAPbIBr | TiO₂ | SUS (50 | 1.02 | 0.35 | 0.74 | 0.26 | 84 | 95 |
| | | | | | μm) | | | | | | |
| | 7 | 6 | CsFAMAPbIBr | TiO₂ | Titanium | 1.02 | 23.4 | 0.73 | 17.42 | 83 | 87 |
| | | | | | foil | | | | | | |
| | | | | | (50 μm) | | | | | | |
| | 8 | 5 | CsFAMAPbIBr | TiO₂ | Titanium | 1.03 | 19.5 | 0.74 | 14.86 | 83 | 90 |
| | | | | | foil | | | | | | |
| | | | | | (50 μm) | | | | | | |
| | 9 | 4 | CsFAMAPbIBr | TiO₂ | Titanium | 1.12 | 13.0 | 0.71 | 10.34 | 85 | 88 |
| | | | | | foil | | | | | | |
| | | | | | (50 μm) | | | | | | |
| | 10 | 3 | CsFAMAPbIBr | TiO₂ | Titanium | 1.09 | 6.50 | 0.71 | 5.03 | 88 | 92 |
| | | | | | foil | | | | | | |
| | | | | | (50 μm) | | | | | | |
| | 11 | 2 | CsFAMAPbIBr | TiO₂ | Titanium | 1.12 | 2.17 | 0.73 | 1.77 | 85 | 94 |
| | | | | | foil | | | | | | |
| | | | | | (50 μm) | | | | | | |
| | 12 | 1 | CsFAMAPbIBr | TiO₂ | Titanium | 1.04 | 0.36 | 0.7 | 0.26 | 83 | 89 |
| | | | | | foil | | | | | | |
| | | | | | (50 μm) | | | | | | |
| | 13 | 2.4 | CsFAMAPbIBr | TiO₂ | PET (125 | 1.01 | 22.9 | 0.71 | 16.42 | 84 | 90 |
| | | | | | μm) | | | | | | |
| | 14 | 2 | CsFAMAPbIBr | TiO₂ | PET (125 | 1.03 | 19.1 | 0.72 | 14.15 | 85 | 93 |
| | | | | | μm) | | | | | | |
| | 15 | 1.6 | CsFAMAPbIBr | TiO₂ | PET (125 | 1.08 | 12.7 | 0.71 | 9.76 | 92 | 88 |
| | | | | | μm) | | | | | | |
| | 16 | 1.2 | CsFAMAPbIBr | TiO₂ | PET (125 | 1.09 | 6.36 | 0.72 | 4.99 | 90 | 90 |
| | | | | | μm) | | | | | | |
| | 17 | 0.8 | CsFAMAPbIBr | TiO₂ | PET (125 | 1.03 | 2.12 | 0.7 | 1.53 | 88 | 89 |
| | | | | | μm) | | | | | | |
| | 18 | 0.4 | CsFAMAPbIBr | TiO₂ | PET (125 | 1.03 | 0.35 | 0.73 | 0.27 | 84 | 88 |
| | | | | | μm) | | | | | | |
| | 19 | 4 | CsFAMAPbIBr | SnO₂ | SUS (50 | 1.12 | 12.8 | 0.72 | 10.32 | 84 | 91 |
| | | | | | μm) | | | | | | |
| | 20 | 4 | CsFAPbIBr | SnO₂ | SUS (50 | 1.08 | 12.4 | 0.73 | 9.77 | 91 | 80 |
| | | | | | μm) | | | | | | |
| | 21 | 3 | CsFAMAPbIBr | SnO₂ | Titanium | 1.1 | 6.7 | 0.7 | 5.16 | 89 | 92 |
| | | | | | foil | | | | | | |
| | | | | | (50 μm) | | | | | | |
| | 22 | 3 | CsFAPbIBr | SnO₂ | Titanium | 1.1 | 6.6 | 0.71 | 5.15 | 82 | 86 |
| | | | | | foil | | | | | | |
| | | | | | (50 μm) | | | | | | |
| | 23 | 1.2 | CsFAMAPbIBr | SnO₂ | PET (125 | 1.12 | 6.60 | 0.73 | 5.40 | 92 | 90 |
| | | | | | μm) | | | | | | |
| | 24 | 1.2 | CsFAPbIBr | SnO₂ | PET (125 | 1.09 | 6.20 | 0.7 | 4.73 | 90 | 91 |
| | | | | | μm) | | | | | | |
| | 25 | 4 | FAMAPbIBr | TiO₂ | SUS (50 | 0.92 | 11.1 | 0.68 | 8.36 | 72 | 70 |
| | | | | | μm) | | | | | | |
| | 26 | 3 | CsFAPbIBr | TiO₂ | Titanium | 1.16 | 7.3 | 0.73 | 6.18 | 87 | 90 |
| | | | | | foil | | | | | | |
| | | | | | (50 μm) | | | | | | |
| | 27 | 1.2 | RbCsFAMAPbIBr | TiO₂ | PET (125 | 1.18 | 7.20 | 0.74 | 6.29 | 90 | 87 |
| | | | | | μm) | | | | | | |
| | 28 | 5 | CsFAMAPbIBr | ZnO | SUS (50 | 0.82 | 11.2 | 0.65 | 5.97 | 74 | 71 |
| | | | | | μm) | | | | | | |
| | 29 | 6 | CsFAMAPbIBr | TiO₂ + | SUS (50 | 1.04 | 22.10 | 0.72 | 16.54 | 82 | 88 |
| | | | | Porous | μm) | | | | | | |
| | | | | TiO₂ | | | | | | | |
| | 30 | 6 | CsFAPbIBr | TiO₂ + | SUS (50 | 1.02 | 22.60 | 0.71 | 16.36 | 90 | 87 |
| | | | | Porous | μm) | | | | | | |
| | | | | TiO₂ | | | | | | | |
| | 31 | 4 | CsFAPbIBr | TiO₂ + | SUS (50 | 1.03 | 12.90 | 0.74 | 9.83 | 92 | 81 |
| | | | | Porous | μm) | | | | | | |
| | | | | TiO₂ | | | | | | | |

TABLE 2

| | | <General | | | | Evaluation results | | | | | |
|---|---|---|---|---|---|---|---|---|---|---|---|
| | | Formula 1> | | | | | | | | | (After test at |
| | | Average | | | | | | | | | high |
| | | thickness of | | | | | | | | | temperature |
| | | Perovskite | | | | | | | | | and high |
| | | T₂ (nm)/ | | | | | | | | (After bending | humidity) |
| | | average | Perovskite layer | | | | | | | test) | Maintenance |
| | | thickness of | <X_{α}Y_{β}M_{γ}> | | | | | | | Maintenance | rate after |
| | | support | X: Halogen | Electron | | | | | | rate after first | second |
| | | body T₁ | Y: Alkylamine | transport | Support | Voc | Jsc | | PCE | durability test | durability |
| | | (μm) | M: Metal | layer | body | (V) | (mA/cm²) | FF | (%) | (%) | test (%) |
| Comparative | 1 | 10 | CsFAMAPbIBr | TiO₂ | SUS (50 | 0.98 | 24.1 | 0.69 | 16.30 | 32 | 12 |
| Examples | | | | | μm) | | | | | | |
| | 2 | 9 | CsFAMAPbIBr | TiO₂ | SUS (50 | 0.99 | 23.6 | 0.7 | 16.35 | 43 | 14 |
| | | | | | μm) | | | | | | |
| | 3 | 8 | CsFAMAPbIBr | TiO₂ | SUS (50 | 1.01 | 23.2 | 0.71 | 16.64 | 55 | 13 |
| | | | | | μm) | | | | | | |
| | 4 | 7 | CsFAMAPbIBr | TiO₂ | SUS (50 | 1.03 | 22.70 | 0.72 | 16.83 | 67 | 26 |
| | | | | | μm) | | | | | | |
| | 5 | 10 | CsFAMAPbIBr | TiO₂ | Titanium | 0.96 | 24.00 | 0.63 | 14.52 | 42 | 21 |
| | | | | | foil | | | | | | |
| | | | | | (50 μm) | | | | | | |
| | 6 | 9 | CsFAMAPbIBr | TiO₂ | Titanium | 0.98 | 24.50 | 0.63 | 15.13 | 53 | 19 |
| | | | | | foil | | | | | | |
| | | | | | (50 μm) | | | | | | |
| | 7 | 8 | CsFAMAPbIBr | TiO₂ | Titanium | 1 | 23.4 | 0.65 | 15.21 | 62 | 22 |
| | | | | | foil | | | | | | |
| | | | | | (50 μm) | | | | | | |
| | 8 | 7 | CsFAMAPbIBr | TiO₂ | Titanium | 1.02 | 22.3 | 0.64 | 14.56 | 74 | 17 |
| | | | | | foil | | | | | | |
| | | | | | (50 μm) | | | | | | |
| | 9 | 10 | CsFAMAPbIBr | TiO₂ | PET (125 | 0.82 | 22.3 | 0.62 | 11.34 | 20 | 18 |
| | | | | | μm) | | | | | | |
| | 10 | 9 | CsFAMAPbIBr | TiO₂ | PET (125 | 0.83 | 22.50 | 0.61 | 11.39 | 33 | 20 |
| | | | | | μm) | | | | | | |
| | 11 | 8 | CsFAMAPbIBr | TiO₂ | PET (125 | 0.88 | 22 | 0.63 | 12.20 | 43 | 21 |
| | | | | | μm) | | | | | | |
| | 12 | 7 | CsFAMAPbIBr | TiO₂ | PET (125 | 0.85 | 22.8 | 0.61 | 11.82 | 56 | 22 |
| | | | | | μm) | | | | | | |
| | 13 | 9 | FAMAPbIBr | TiO₂ | SUS (50 | 0.83 | 22.1 | 0.67 | 12.29 | 32 | 12 |
| | | | | | μm) | | | | | | |

The meaning of each symbol in Tables 1 and 2 is as follows.
“Voc” refers to an open-circuit voltage.
“Jsc” refers to a short-circuit current density.
“EF” refers to a form factor.
“PCE” refers to a photoelectric conversion efficiency.

In Table 1 below, methylammonium is indicated as “MA” and formamidinium is indicated as “FA” in the composition of the perovskite layer.

From the results of Tables 1 and 2 and FIG. 19, the average thickness T₁ (μm) of the support body (first substrate) and the average thickness T₂ (nm) of the perovskite layer satisfy the relationship T₂/T₁≤6, and therefore, the photoelectric conversion efficiency was maintained even after the test at high temperature and high humidity. That is, it was understood that a high output can be maintained even after performing a test further promoting the generation of cracks after the bending test.

For example, aspects of the present embodiment include the following.

<1> A photoelectric conversion element including a support body having flexibility, a perovskite layer, and a second electrode, in which an average thickness T₁ (μm) of the support body and an average thickness T₂ (nm) of the perovskite layer satisfy a relationship T₂/T₁≤6.

<2> The photoelectric conversion element according to <1> described above, further including an electron transport layer containing at least one of tin oxide and titanium oxide.

<3> The photoelectric conversion element according to <2> described above, in which the electron transport layer includes a dense layer.

<4> The photoelectric conversion element according to any one of <2> and <3> described above, in which the electron transport layer further includes a porous layer.

<5> The photoelectric conversion element according to any one of <1> to <4> described above, in which the perovskite layer includes at least one of an alkali metal and a transition metal.

<6> The photoelectric conversion element according to <5> described above, in which the alkali metal includes at least one of lithium, sodium, potassium, rubidium, cesium, and francium, and the transition metal includes at least one of copper, silver, and gold.

<7> The photoelectric conversion element according to any one of <1> to <6> described above, in which the perovskite layer includes two or more types of monovalent cations selected from monovalent organic cations and monovalent inorganic cations.

<8> The photoelectric conversion element according to any one of <1> to <7> described above, in which the average thickness T₂ (nm) of the perovskite layer is 50 nm or more and 400 nm or less.

<9> The photoelectric conversion element according to any one of <1> to <8> described above, in which the average thickness T₁ (μm) of the support body is 30 μm or more and 1300 μm or less.

<10> A photoelectric conversion module including a support body having flexibility, a perovskite layer, and a second electrode, in which an average thickness T₁ (μm) of the support body and an average thickness T₂ (nm) of the perovskite layer satisfy a relationship T₂/T₁≤6.

<11> An electronic device including any one of the photoelectric conversion elements according to <1> to <9> described above and the photoelectric conversion module according to <10> described above, and a device configured to operate on electric power generated by photoelectric conversion by the any one of the photoelectric conversion elements and the photoelectric conversion module.

<12> A solar cell module including photoelectric conversion elements connected in series or in parallel, in which the photoelectric conversion elements each include a support body having flexibility, a perovskite layer, and a second electrode, and an average thickness T₁ (μm) of the support body and an average thickness T₂ (nm) of the perovskite layer satisfy a relationship T₂/T₁≤6.

<13> An electronic device including any one of the photoelectric conversion elements according to <1> to <9> described above and the photoelectric conversion module according to <10> described above, a storage battery that stores electric power generated by photoelectric conversion by the any one of the photoelectric conversion elements and the photoelectric conversion module, and a device configured to operate on the electric power stored in the storage battery.

According to the photoelectric conversion element according to any one of <1> to <9> described above, the photoelectric conversion module according to <10> described above, the solar cell module according to <12> described above, and the electronic device according to any one of <11> to <13> described above, it is possible to solve various conventional problems and achieve the object of the present embodiment.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

This patent application is based on and claims priority to Japanese Patent Application No. 2022-044140, filed on Mar. 18, 2022, in the Japan Patent Office, the entire disclosure of which is hereby incorporated by reference herein.

### REFERENCE SIGNS LIST

1 First substrate
2, 2a, 2b First electrode
3 Electron transport layer, Dense layer
4 Porous layer
5 Perovskite layer
6 Layer of a compound represented by General Formula (2)
7 Hole transport layer
8, 8a, 8b Second electrode
9 Through portion
10 Sealing member
11 Second substrate
100, 101, 102, 103, 104 Solar cell module
201 Photoelectric conversion element
202 Power supply IC
203 Power storage device
204 Control circuit of mouse
205 Control circuit of keyboard
206 Sensor circuit
207 Device
208 Turntable control circuit
209 Device circuit

1. A photoelectric conversion element, comprising:
a support body having flexibility;
a perovskite layer; and
a second electrode,
wherein an average thickness T₁ (μm) of the support body and an average thickness T₂ (nm) of the perovskite layer satisfy a relationship T₂/T₁≤6.

2. The photoelectric conversion element according to claim 1, further comprising:
an electron transport layer including at least one of tin oxide and titanium oxide.

3. The photoelectric conversion element according to claim 2, wherein:
the electron transport layer includes a dense layer.

4. The photoelectric conversion element according to claim 2, wherein:
the electron transport layer further includes a porous layer.

5. The photoelectric conversion element according to claim 1, wherein:
the perovskite layer includes at least one of an alkali metal and a transition metal.

6. The photoelectric conversion element according to claim 5, wherein:
the alkali metal includes at least one of lithium, sodium, potassium, rubidium, cesium, and francium, and the transition metal includes at least one of copper, silver, and gold.

7. The photoelectric conversion element according to claim 1, wherein:
the perovskite layer includes two or more types of monovalent cations selected from monovalent organic cations and monovalent inorganic cations.

8. The photoelectric conversion element according to claim 1, wherein:
the average thickness T₂ (nm) of the perovskite layer is 50 nm or more and 400 nm or less.

9. The photoelectric conversion element according to claim 1, wherein:
the average thickness T₁ (μm) of the support body is 30 μm or more and 1300 μm or less.

10. A photoelectric conversion module, comprising:
a support body having flexibility;
a perovskite layer; and
a second electrode,
wherein an average thickness T₁ (μm) of the support body and an average thickness T₂ (nm) of the perovskite layer satisfy a relationship T₂/T₁≤6.

11. An electronic device, comprising:
at least one of the photoelectric conversion element according to claim 1, and a photoelectric conversion module including:
a support body having flexibility;
a perovskite layer, an average thickness T₁ (μm) of the support body and an average thickness T₂ (nm) of the perovskite layer satisfy a relationship T₂/T₁≤6; and
a second electrode, and
a device to operate on electric power generated by photoelectric conversion by the any one of the photoelectric conversion element and the photoelectric conversion module.

12. A solar cell module, comprising:
photoelectric conversion elements connected in series or in parallel,
wherein the photoelectric conversion elements each include:
a support body having flexibility;
a perovskite layer; and
a second electrode, and
an average thickness T₁ (μm) of the support body and an average thickness T₂ (nm) of the perovskite layer satisfy a relationship T₂/T₁≤6.
